(19) United States
(12) Patent Application Publication
(10) Pub. No.: US 2025/0378362 A1
(43) Pub. Date: Dec. 11, 2025

(54) Performing a Multi-qubit Stabilizer Measurement

(71) Applicant: Rigetti & Co, LLC, Berkeley, CA (US)

(72) Inventors: Matthew J. Reagor, San Rafael, CA (US); David Rodriguez Perez, Ketchikan, AK (US)

(73) Assignee: Rigetti & Co, LLC, Berkeley, CA (US)

(21) Appl. No.: 18/735,680

(22) Filed: Jun. 6, 2024

Related U.S. Application Data
(63) Continuation of application No. PCT/US2022/081813, filed on Dec. 16, 2022.
(60) Provisional application No. 63/290,453, filed on Dec. 16, 2021.

(51) Int. Cl. G06N 10/70; G06N 10/20; G06N 10/40

(52) U.S. Cl. CPC G06N 10/70; G06N 10/20; G06N 10/40

(57) ABSTRACT

In a general aspect, a multi-qubit quantum logic gate for a multi-qubit hardware-efficient stabilizer measurement is performed. In some implementations, a superconducting quantum processing unit includes a stabilizer check qubit device and two or more data qubit devices operably coupled to the stabilizer check qubit device through respective tunable-frequency coupler devices. A method includes applying a multi-qubit quantum logic gate on the stabilizer check qubit device and the two or more data qubit devices. Applying the multi-qubit quantum logic gate includes evolving the stabilizer check qubit device and the two or more data qubit devices under an interaction Hamiltonian with a plurality of terms. Each of the plurality of terms corresponding to an interaction between the stabilizer check qubit device and a respective one of the two or more data qubit devices, includes a phase combined with a Pauli operator applied to the stabilizer check qubit device and the Pauli operator applied to the respective one of the two or more data qubit devices.

### CROSS-REFERENCE TO RELATED APPLICATIONS

This application claims priority to U.S. Provisional Patent Application No. 63/290,453, filed Dec. 16, 2021, entitled “Hardware Efficient Stabilizer Measurements in Circuit QED.” The above-referenced priority document is incorporated herein by reference in its entirety.

### TECHNICAL FIELD

The following description relates to performing a multi-qubit stabilizer measurement.

### BACKGROUND

Quantum computers can perform computational tasks by storing and processing information within quantum states of quantum systems. For example, qubits (i.e., quantum bits) can be stored in, and represented by, an effective two-level sub-manifold of a quantum coherent physical system. A variety of physical systems have been proposed for quantum computing applications. Examples include superconducting circuits, trapped ions, spin systems, and others.

### BRIEF DESCRIPTION OF THE DRAWINGS

FIG. 1 is a block diagram of an example computing environment.

FIG. 2A includes schematic diagrams showing aspects of example quantum logic circuits.

FIG. 2B includes schematic diagrams showing aspects of example quantum logic circuits.

FIG. 2C is a schematic diagram showing aspects of an example quantum logic circuit.

FIG. 2D is a schematic diagram showing aspects of an example quantum logic circuit.

FIG. 3A is a plot showing the [symbol] σ^{x} [symbol] value of the stabilizer check qubit device in a range of 1 and −1 as a function of time in microseconds (μs) without a presence of error (error-free) for different cases of parity in the data qubit devices in FIG. 2D.

FIG. 3B is a plot showing the [symbol] σ^{x} [symbol] value in a range of 1 and −1 as a function of time in microseconds (μs) with a presence of dephasing (Γ_{ϕ}=0.01 MHz) for different cases of parity in the data qubit devices in FIG. 2D.

FIG. 3C is a plot showing the [symbol] σ^{x} [symbol] value in a range of 1 and −1 as a function of time in microseconds (μs) with a presence of decoherence (dephasing and energy loss, Γ₁=0.1 MHz) for different cases of parity in the data qubit devices in FIG. 2D.

FIG. 4 is a schematic diagram showing aspects of an example quantum computing system.

FIG. 5 are schematic diagrams of a top view and a cross-sectional view of an example quantum processing unit.

FIG. 6 is a circuit diagram showing an example equivalent circuit of the example quantum processing unit in FIG. 5.

FIG. 7 is a plot showing qubit-qubit ZZ coupling strength (χ/2π) in MHz between the two tunable-frequency qubit devices as a function of the coupler frequency in GHz of the tunable-frequency coupler device shown in FIG. 5.

FIG. 8 is a flow chart showing aspects of an example process for performing a multi-qubit stabilizer measurement.

### DETAILED DESCRIPTION

In some aspects of what is described here, an error correcting surface code based on multi-qubit stabilizer measurements is used to realize fault-tolerant quantum logic steps for error correction in quantum computers. A multi-qubit stabilizer measurement is applied on qubits implemented by superconducting qubit devices in a superconducting quantum processing unit based on strong-dispersive interactions offered by tunable-coupler devices between respective pairs of qubit devices.

In some implementations, the systems and techniques described here can provide and/or facilitate technical advantages and improvements. The methods and techniques presented here may enable a superconducting processing unit that are capable of achieving different error profiles and performing efficient stabilizer quantum error correction. The methods and techniques presented here can, in some cases, reduce the requirements for fault-tolerance while taking advantage of the investment towards machines for near-term quantum applications. The methods and techniques presented here can reduce the system calibration problem to a single gate per check and can have error correction advantages for near-term machines due to a higher threshold, a lower logical qubit error rate, and reduced physical overhead compared to equivalent sequences of two-qubit quantum logic gates. In some implementations, a multi-qubit stabilizer measurement may enable efficient heat management in large-scale superconducting processing unit, reduces passive and active heat load at the lowest-temperature stages of the dilution refrigerator, and thus the total thermal budget. A multi-qubit stabilizer measurement can allow for an equal thermal footprint while doubling the number of physical qubit devices. In some cases, a combination of these and potentially other advantages and improvements may be obtained.

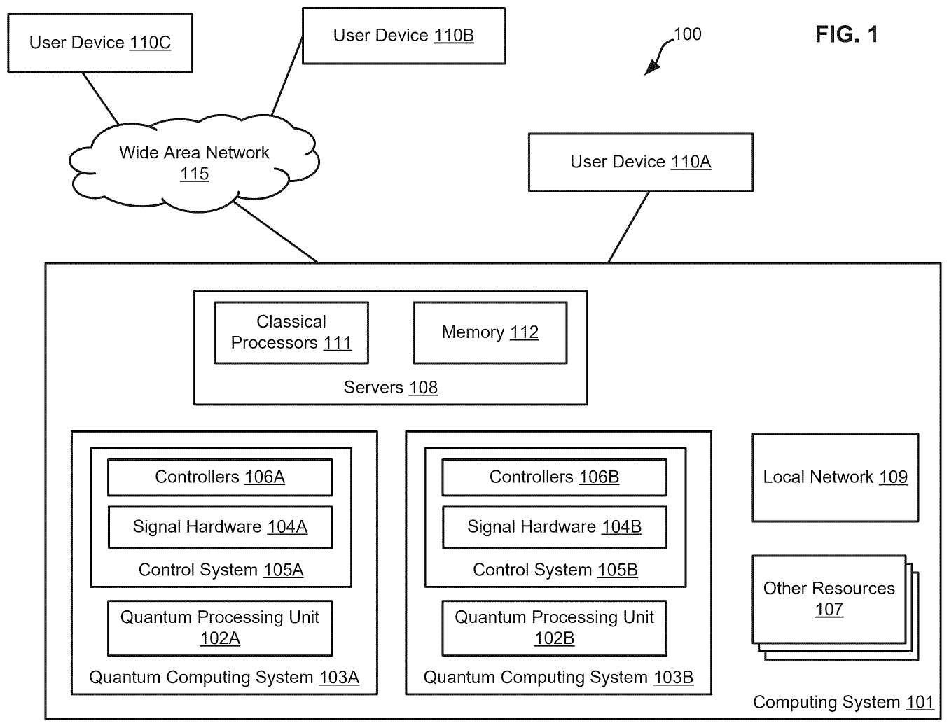

FIG. 1 is a block diagram of an example computing environment 100. The example computing environment 100 shown in FIG. 1 includes a computing system 101 and user devices 110A, 110B, 110C. A computing environment may include additional or different features, and the components of a computing environment may operate as described with respect to FIG. 1 or in another manner.

The example computing system 101 includes classical and quantum computing resources and exposes their functionality to the user devices 110A, 110B, 110C (referred to collectively as “user devices 110”). The computing system 101 shown in FIG. 1 includes one or more servers 108, quantum computing systems 103A, 103B, a local network 109, and other resources 107. The computing system 101 may also include one or more user devices (e.g., the user device 110A) as well as other features and components. A computing system may include additional or different features, and the components of a computing system may operate as described with respect to FIG. 1 or in another manner.

The example computing system 101 can provide services to the user devices 110, for example, as a cloud-based or remote-accessed computer system, as a distributed computing resource, as a supercomputer or another type of high-performance computing resource, or in another manner. The computing system 101 or the user devices 110 may also have access to one or more other quantum computing systems (e.g., quantum computing resources that are accessible through the wide area network 115, the local network 109, or otherwise).

The user devices 110 shown in FIG. 1 may include one or more classical processors, memory, user interfaces, communication interfaces, and other components. For instance, the user devices 110 may be implemented as laptop computers, desktop computers, smartphones, tablets, or other types of computer devices. In the example shown in FIG. 1, to access computing resources of the computing system 101, the user devices 110 send information (e.g., programs, instructions, commands, requests, input data, etc.) to the servers 108; and in response, the user devices 110 receive information (e.g., application data, output data, prompts, alerts, notifications, results, etc.) from the servers 108. The user devices 110 may access services of the computing system 101 in another manner, and the computing system 101 may expose computing resources in another manner.

In the example shown in FIG. 1, the local user device 110A operates in a local environment with the servers 108 and other elements of the computing system 101. For instance, the user device 110A may be co-located with (e.g., located within 0.5 to 1 km of) the servers 108 and possibly other elements of the computing system 101. As shown in FIG. 1, the user device 110A communicates with the servers 108 through a local data connection.

The local data connection in FIG. 1 is provided by the local network 109. For example, some or all of the servers 108, the user device 110A, the quantum computing systems 103A, 103B, and the other resources 107 may communicate with each other through the local network 109. In some implementations, the local network 109 operates as a communication channel that provides one or more low-latency communication pathways from the server 108 to the quantum computing systems 103A, 103B (or to one or more of the elements of the quantum computing systems 103A, 103B). The local network 109 can be implemented, for instance, as a wired or wireless Local Area Network, an Ethernet connection, or another type of wired or wireless connection. The local network 109 may include one or more wired or wireless routers, wireless access points (WAPs), wireless mesh nodes, switches, high-speed cables, or a combination of these and other types of local network hardware elements. In some cases, the local network 109 includes a software-defined network that provides communication among virtual resources, for example, among an array of virtual machines operating on the server 108 and possibly elsewhere.

In the example shown in FIG. 1, the remote user devices 110B, 110C operate remote from the servers 108 and other elements of the computing system 101. For instance, the user devices 110B, 110C may be located at a remote distance (e.g., more than 1 km, 10 km, 100 km, 1,000 km, 10,000 km, or farther) from the servers 108 and possibly other elements of the computing system 101. As shown in FIG. 1, each of the user devices 110B, 110C communicates with the servers 108 through a remote data connection.

The remote data connection in FIG. 1 is provided by a wide area network 115, which may include, for example, the Internet or another type of wide area communication network. In some cases, remote user devices use another type of remote data connection (e.g., satellite-based connections, a cellular network, a virtual private network, etc.) to access the servers 108. The wide area network 115 may include one or more internet servers, firewalls, service hubs, base stations, or a combination of these and other types of remote networking elements. Generally, the computing environment 100 can be accessible to any number of remote user devices.

The example servers 108 shown in FIG. 1 can manage interaction with the user devices 110 and utilization of the quantum and classical computing resources in the computing system 101. For example, based on information from the user devices 110, the servers 108 may delegate computational tasks to the quantum computing systems 103A, 103B and the other resources 107; the servers 108 can then send information to the user devices 110 based on output data from the computational tasks performed by the quantum computing systems 103A, 103B, and the other resources 107.

As shown in FIG. 1, the servers 108 are classical computing resources that include classical processors 111 and memory 112. The servers 108 may also include one or more communication interfaces that allow the servers to communicate via the local network 109, the wide area network 115, and possibly other channels. In some implementations, the servers 108 may include a host server, an application server, a virtual server, or a combination of these and other types of servers. The servers 108 may include additional or different features, and may operate as described with respect to FIG. 1 or in another manner.

The classical processors 111 can include various kinds of apparatus, devices, and machines for processing data, including, by way of example, a microprocessor, a central processing unit (CPU), a graphics processing unit (GPU), an FPGA (field programmable gate array), an ASIC (application specific integrated circuit), or combinations of these. The memory 112 can include, for example, a random-access memory (RAM), a storage device (e.g., a writable read-only memory (ROM) or others), a hard disk, or another type of storage medium. The memory 112 can include various forms of volatile or non-volatile memory, media, and memory devices, etc.

Each of the example quantum computing systems 103A, 103B operates as a quantum computing resource in the computing system 101. The other resources 107 may include additional quantum computing resources (e.g., quantum computing systems, quantum simulators, or both) as well as classical (non-quantum) computing resources such as, for example, digital microprocessors, specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), etc., or combinations of these and other types of computing modules.

In some implementations, the servers 108 generate programs, identify appropriate computing resources (e.g., a QPU or QVM) in the computing system 101 to execute the programs, and send the programs to the identified resources for execution. For example, the servers 108 may send programs to the quantum computing system 103A, the quantum computing system 103B, or any of the other resources 107. The programs may include classical programs, quantum programs, hybrid classical/quantum programs, and may include any type of function, code, data, instruction set, etc.

In some instances, programs can be formatted as source code that can be rendered in human-readable form (e.g., as text) and can be compiled, for example, by a compiler running on the servers 108, on the quantum computing systems 103, or elsewhere. In some instances, programs can be formatted as compiled code, such as, for example, binary code (e.g., machine-level instructions) that can be executed directly by a computing resource. Each program may include instructions corresponding to computational tasks that, when performed by an appropriate computing resource, generate output data based on input data. For example, a program can include instructions formatted for a quantum computer system, a simulator, a digital microprocessor, co-processor or other classical data processing apparatus, or another type of computing resource.

In some cases, a program may be expressed in a hardware-independent format. For example, quantum machine instructions may be provided in a quantum instruction language such as Quil, described in the publication “A Practical Quantum Instruction Set Architecture,” arXiv:1608.03355v2, dated Feb. 17, 2017, or another quantum instruction language. For instance, the quantum machine instructions may be written in a format that can be executed by a broad range of quantum processing units or simulators. In some cases, a program may be expressed in high-level terms of quantum logic gates or quantum algorithms, in lower-level terms of fundamental qubit rotations and controlled rotations, or in another form. In some cases, a program may be expressed in terms of control signals (e.g., pulse sequences, delays, etc.) and parameters for the control signals (e.g., frequencies, phases, durations, channels, etc.). In some cases, a program may be expressed in another form or format. In some cases, a program may utilize Quil-T, described in the publication “Gain deeper control of Rigetti quantum processing units with Quil-T,” available at https://medium.com/rigetti/gain-deeper-control-of-rigetti-quantum-processors-with-quil-t-ea8945061e5b dated Dec. 10, 2020, which is hereby incorporated by reference in the present disclosure.

In some implementations, the servers 108 include one or more compilers that convert programs between formats. For example, the servers 108 may include a compiler that converts hardware-independent instructions to binary programs for execution by the quantum computing systems 103A, 103B. In some cases, a compiler can compile a program to a format that targets a specific quantum resource in the computer system 101. For example, a compiler may generate a different binary program (e.g., from the same source code) depending on whether the program is to be executed by the quantum computing system 103A or the quantum computing system 103B.

In some cases, a compiler generates a partial binary program that can be updated, for example, based on specific parameters. For instance, if a quantum program is to be executed iteratively on a quantum computing system with varying parameters on each iteration, the compiler may generate the binary program in a format that can be updated with specific parameter values at runtime (e.g., based on feedback from a prior iteration, or otherwise); the parametric update can be performed without further compilation. In some cases, a compiler generates a full binary program that does not need to be updated or otherwise modified for execution.

In some implementations, the servers 108 generate a schedule for executing programs, allocate computing resources in the computing system 101 according to the schedule, and delegate the programs to the allocated computing resources. The servers 108 can receive, from each computing resource, output data from the execution of each program. Based on the output data, the servers 108 may generate additional programs that are then added to the schedule, output data that is provided back to a user device 110, or perform another type of action.

In some implementations, all or part of the computing system 101 operates as a hybrid computing environment. For example, quantum programs can be formatted as hybrid classical/quantum programs that include instructions for execution by one or more quantum computing resources and instructions for execution by one or more classical resources. The servers 108 can allocate quantum and classical computing resources in the hybrid computing environment, and delegate programs to the allocated computing resources for execution. The quantum computing resources in the hybrid environment may include, for example, one or more quantum processing units (QPUs), one or more quantum virtual machines (QVMs), one or more quantum simulators, or possibly other types of quantum resources. The classical computing resources in the hybrid environment may include, for example, one or more digital microprocessors, one or more specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), or other types of computing modules.

In some cases, the servers 108 can select the type of computing resource (e.g., quantum or classical) to execute an individual program, or part of a program, in the computing system 101. For example, the servers 108 may select a particular quantum processing unit (QPU) or other computing resource based on availability of the resource, speed of the resource, information or state capacity of the resource, a performance metric (e.g., process fidelity) of the resource, or based on a combination of these and other factors. In some cases, the servers 108 can perform load balancing, resource testing and calibration, and other types of operations to improve or optimize computing performance.

Each of the example quantum computing systems 103A, 103B shown in FIG. 1 can perform quantum computational tasks by executing quantum machine instructions (e.g., a binary program compiled for the quantum computing system). In some implementations, a quantum computing system can perform quantum computation by storing and manipulating information within quantum states of a composite quantum system. For example, qubits (i.e., quantum bits) can be stored in, and represented by, an effective two-level sub-manifold of a quantum coherent physical system. In some instances, quantum logic can be executed in a manner that allows large-scale entanglement within the quantum system. Control signals can manipulate the quantum states of individual qubits and the joint states of multiple qubits. In some instances, information can be read out from the composite quantum system by measuring the quantum states of the qubits. In some implementations, the quantum states of the qubits are read out by measuring the transmitted or reflected signal from auxiliary quantum devices that are coupled to individual qubits.

In some implementations, a quantum computing system can operate using gate-based models for quantum computing. For example, the qubits can be initialized in an initial state, and a quantum logic circuit comprised of a series of quantum logic gates can be applied to transform the qubits and extract measurements representing the output of the quantum computation. Individual qubits may be controlled by single-qubit quantum logic gates, and pairs of qubits may be controlled by two-qubit quantum logic gates (e.g., entangling gates that are capable of generating entanglement between the pair of qubits). In some implementations, a quantum computing system can operate using adiabatic or annealing models for quantum computing. For instance, the qubits can be initialized in an initial state, and the controlling Hamiltonian can be transformed adiabatically by adjusting control parameters to another state that can be measured to obtain an output of the quantum computation.

In some models, fault-tolerance can be achieved by applying a set of high-fidelity control and measurement operations to the qubits. For example, quantum error correcting codes can be deployed to achieve fault-tolerant quantum computation. Other computational regimes may be used; for example, quantum computing systems may operate in non-fault-tolerant regimes. In some implementations, a quantum computing system is constructed and operated according to a scalable quantum computing architecture. For example, in some cases, the architecture can be scaled to a large number of qubits to achieve large-scale general purpose coherent quantum computing. Other architectures may be used; for example, quantum computing systems may operate in small-scale or non-scalable architectures.

The example quantum computing system 103A shown in FIG. 1 includes a quantum processing unit 102A and a control system 105A, which controls the operation of the quantum processing unit 102A. Similarly, the example quantum computing system 103B includes a quantum processing unit 102B and a control system 105B, which controls the operation of a quantum processing unit 102B. A quantum computing system may include additional or different features, and the components of a quantum computing system may operate as described with respect to FIG. 1 or in another manner.

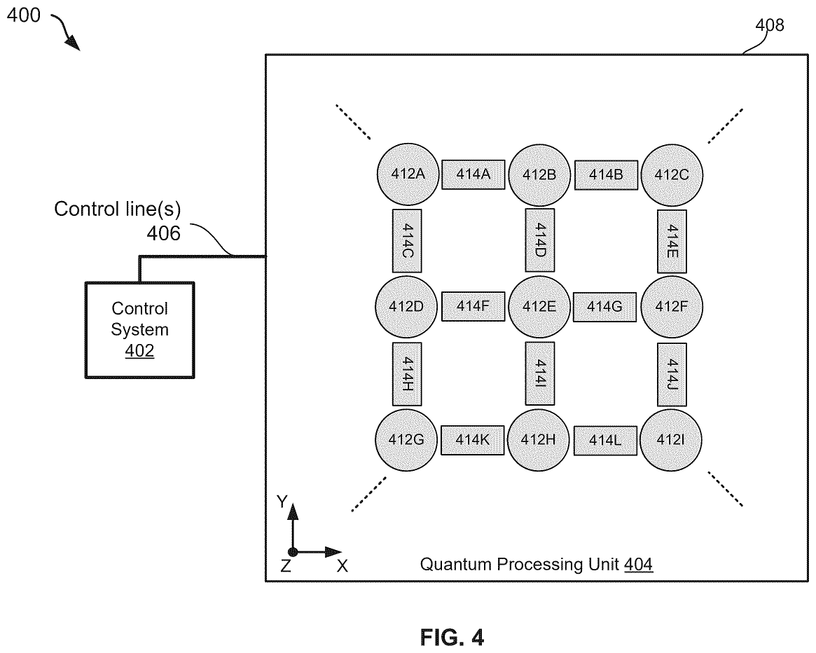

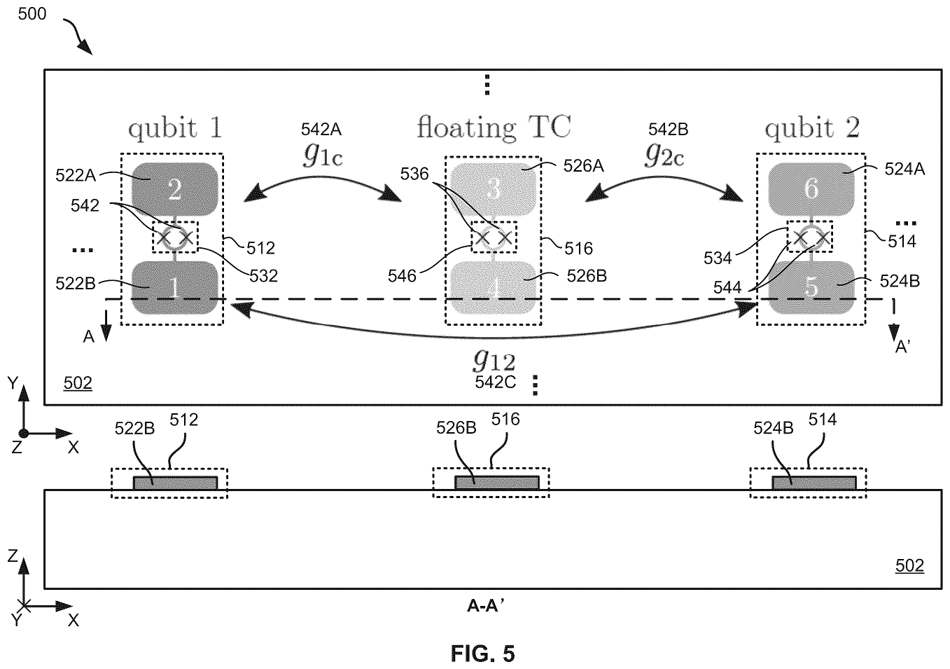

In some instances, all or part of the quantum processing unit 102A functions as a quantum processing unit, a quantum memory, or another type of subsystem. In some examples, the quantum processing unit 102A includes a superconducting quantum circuit system. The superconducting quantum circuit may include data qubit devices, stabilizer qubit devices, coupler devices, readout devices, and possibly other devices that are used to store and process quantum information. In some cases, multiple data qubit devices are operatively coupled to a single stabilizer check qubit device through respective coupler devices. In some implementations, the quantum processing unit 102A is implemented as the quantum processing unit 404, 500 shown in FIGS. 4 and 5, or in another manner. In certain examples, the qubit devices and the coupler devices are implemented as superconducting quantum circuit devices that include Josephson junctions, for example, in Superconducting QUantum Interference Device (SQUID) loops or other arrangements, and are controlled by radio-frequency signals, microwave signals, and bias signals delivered to the quantum processing unit 102A. In some instances, a qubit device of the quantum processing unit 102A is a physical implementation of a multi-dimensional quantum system, e.g., a qudit. In some examples, a multi-level quantum system may be a two-level quantum system which includes two lowest energy levels (e.g., the ground state |0 [symbol] and a first excited state |1 [symbol] ) used as computational basis states for quantum computation. In some examples, a multi-level quantum system also includes higher energy levels (e.g., a second excited state |2 [symbol] or a third excited state |3 [symbol] ) used as computational basis states for quantum computation in some instances.

In some instances, the quantum processing units can include a superconducting quantum circuit that includes one or more quantum circuit devices. For instance, a superconducting quantum circuit may include qubit devices, readout resonator devices, Josephson junctions, or other quantum circuit devices. In some implementations, multiple quantum circuit devices in a quantum processing unit can be collectively operated to define a single logical qubit. A logical qubit includes a quantum register, for instance multiple qubit devices, and associated circuitry, that supports computational operations which can be used to detect or correct errors associated with logical states in a quantum algorithm. Computational operations supported by the quantum register associated with a logical qubit may include single-qubit or multi-qubit quantum logic gates and readout mechanisms. Error detection or correction mechanisms associated with a logical qubit may be based on quantum error correction schemes such as the surface code, color code, Bacon-Shor codes, low-density parity check codes (LDPC), some combination of these, or others.

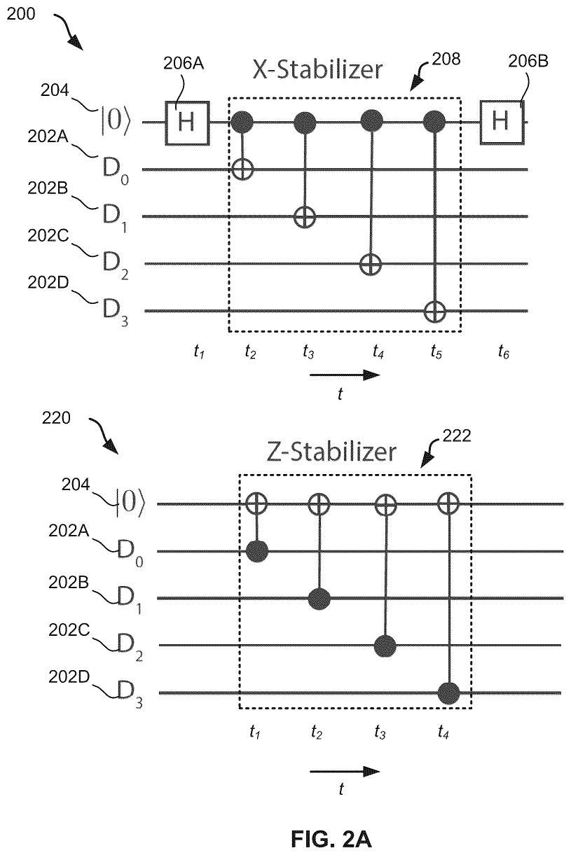

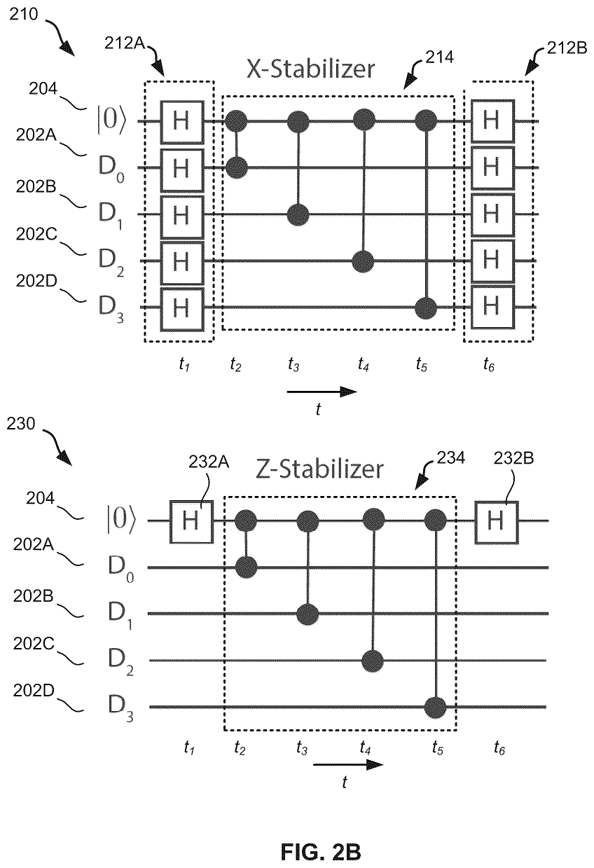

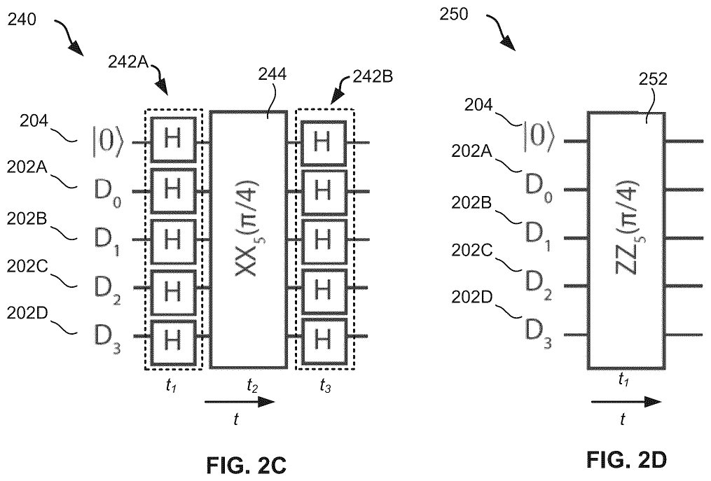

In some implementations, a quantum error correction code based on multi-qubit stabilizer measurements is implemented on the superconducting quantum processing unit 102A. In some implementations, applying a multi-qubit stabilizer measurement includes applying a multi-qubit quantum logic gate on qubits implemented by superconducting qubit devices. A multi-qubit stabilizer measurement is a single parity check operation defined by strong, multi-qubit dispersive ZZ interactions between multiple data qubit devices and a stabilizer check qubit device, which are coupled by tunable-frequency coupler devices. As used herein in this context, the term “strong” may refer in some cases to 1 MHz of coupling or more. Additionally or alternatively, the term “strong” in the context of multi-qubit dispersive ZZ interactions may refer to a rate that is 10 times or more than the rate of a single qubit decoherence as may be typical. The multi-qubit quantum logic gate for performing a multi-qubit stabilizer measurement, e.g., the ZZₙ(θ) gate 252 in FIG. 2D, is logically equivalent to a series of CZ gates (e.g., the

$${U}_{CZ}^{⊗ 4}$$

gate in the quantum logic circuit 210 and 230 in FIG. 2B).

The quantum processing unit 102A may include, or may be deployed within, a controlled environment. The controlled environment can be provided, for example, by shielding equipment, cryogenic equipment, and other types of environmental control systems. In some examples, the components in the quantum processing unit 102A operate in a cryogenic temperature regime and are subject to very low electromagnetic and thermal noise. For example, magnetic shielding can be used to shield the system components from stray magnetic fields, optical shielding can be used to shield the system components from optical noise, thermal shielding and cryogenic equipment can be used to maintain the system components at controlled temperature, etc.

In some implementations, the example quantum processing unit 102A can process quantum information by applying control signals to the qubits in the quantum processing unit 102A. The control signals can be configured to encode information in the qubits, to process the information by performing quantum logic gates or other types of operations, or to extract information from the qubits. In some examples, the operations can be expressed as single-qubit quantum logic gates, two-qubit quantum logic gates, or other types of quantum logic gates that operate on one or more qubits. A quantum logic circuit, which includes a sequence of quantum logic operations, can be applied to the qubits to perform a quantum algorithm. The quantum algorithm may correspond to a computational task, a hardware test, a quantum error correction procedure, a quantum state distillation procedure, or a combination of these and other types of operations.

The example control system 105A includes controllers 106A and signal hardware 104A. Similarly, control system 105B includes controllers 106B and signal hardware 104B. All or part of the control systems 105A, 105B can operate in a room-temperature environment or another type of environment, which may be located near the respective quantum processing units 102A, 102B. In some cases, the control systems 105A, 105B include classical computers, signaling equipment (microwave, radio, optical, bias, etc.), electronic systems, vacuum control systems, refrigerant control systems, or other types of control systems that support operation of the quantum processing units 102A, 102B.

The control systems 105A, 105B may be implemented as distinct systems that operate independent of each other. In some cases, the control systems 105A, 105B may include one or more shared elements; for example, the control systems 105A, 105B may operate as a single control system that operates both quantum processing units 102A, 102B. Moreover, a single quantum computing system may include multiple quantum processing units, which may operate in the same controlled (e.g., cryogenic) environment or in separate environments.

The example signal hardware 104A includes components that communicate with the quantum processing unit 102A. The signal hardware 104A may include, for example, waveform generators, amplifiers, digitizers, high-frequency sources, DC sources, AC sources, etc. The signal hardware may include additional or different features and components. In the example shown, components of the signal hardware 104A are adapted to interact with the quantum processing unit 102A. For example, the signal hardware 104A can be configured to operate in a particular frequency range, configured to generate and process signals in a particular format, or the hardware may be adapted in another manner.

In some instances, one or more components of the signal hardware 104A generate control signals, for example, based on control information from the controllers 106A. The control signals can be delivered to the quantum processing unit 102A during operation of the quantum computing system 103A. For instance, the signal hardware 104A may generate signals to implement quantum logic operations, readout operations, or other types of operations. As an example, the signal hardware 104A may include arbitrary waveform generators (AWGs) that generate electromagnetic waveforms (e.g., microwave or radio-frequency) or laser systems that generate optical waveforms. The waveforms or other types of signals generated by the signal hardware 104A can be delivered to devices in the quantum processing unit 102A to operate qubit devices, readout devices, bias devices, coupler devices, or other types of components in the quantum processing unit 102A.

In some instances, the signal hardware 104A receives and processes signals from the quantum processing unit 102A. The received signals can be generated by the execution of a quantum program on the quantum computing system 103A. For instance, the signal hardware 104A may receive signals from the devices in the quantum processing unit 102A in response to readout or other operations performed by the quantum processing unit 102A. Signals received from the quantum processing unit 102A can be mixed, digitized, filtered, or otherwise processed by the signal hardware 104A to extract information, and the information extracted can be provided to the controllers 106A or handled in another manner. In some examples, the signal hardware 104A may include a digitizer that digitizes electromagnetic waveforms (e.g., microwave or radio-frequency) or optical signals, and a digitized waveform can be delivered to the controllers 106A or to other signal hardware components. In some instances, the controllers 106A process the information from the signal hardware 104A and provide feedback to the signal hardware 104A; based on the feedback, the signal hardware 104A can in turn generate new control signals that are delivered to the quantum processing unit 102A.

In some implementations, the signal hardware 104A includes signal delivery hardware that interfaces with the quantum processing unit 102A. For example, the signal hardware 104A may include filters, attenuators, directional couplers, multiplexers, diplexers, bias components, signal channels, isolators, amplifiers, power dividers, and other types of components. In some instances, the signal delivery hardware performs preprocessing, signal conditioning, or other operations to the control signals to be delivered to the quantum processing unit 102A. In some instances, signal delivery hardware performs preprocessing, signal conditioning, or other operations on readout signals received from the quantum processing unit 102A.

The example controllers 106A communicate with the signal hardware 104A to control operation of the quantum computing system 103A. The controllers 106A may include classical computing hardware that directly interfaces with components of the signal hardware 104A. The example controllers 106A may include classical processors, memory, clocks, digital circuitry, analog circuitry, and other types of systems or subsystems. The classical processors may include one or more single- or multi-core microprocessors, digital electronic controllers, special purpose logic circuitry, e.g., an FPGA (field programmable gate array) or an ASIC (application specific integrated circuit), or other types of data processing apparatus. The memory may include any type of volatile or non-volatile memory or another type of computer storage medium. The controllers 106A may also include one or more communication interfaces that allow the controllers 106A to communicate via the local network 109 and possibly other channels. The controllers 106A may include additional or different features and components.

In some implementations, the controllers 106A include memory or other components that store quantum state information, for example, based on qubit readout operations performed by the quantum computing system 103A. For instance, the states of one or more qubits in the quantum processing unit 102A can be measured by qubit readout operations, and the measured state information can be stored in a cache or other type of memory system in one or more of the controllers 106A. In some cases, the measured state information is subsequently used in the execution of a quantum program, a quantum error correction procedure, a quantum processing unit (QPU) calibration or testing procedure, or another type of quantum process.

In some implementations, the controllers 106A include memory or other components that store a quantum program containing quantum machine instructions for execution by the quantum computing system 103A. In some instances, the controllers 106A can interpret the quantum machine instructions and perform hardware-specific control operations according to the quantum machine instructions. For example, the controllers 106A may cause the signal hardware 104A to generate control signals that are delivered to the quantum processing unit 102A to execute the quantum machine instructions.

In some instances, the controllers 106A extract qubit state information from qubit readout signals, for example, to identify the quantum states of qubits in the quantum processing unit 102A or for other purposes. For example, the controllers may receive the qubit readout signals (e.g., in the form of analog waveforms) from the signal hardware 104A, digitize the qubit readout signals, and extract qubit state information from the digitized signals. In some cases, the controllers 106A compute measurement statistics based on qubit state information from multiple shots of a quantum program. For example, each shot may produce a bitstring representing qubit state measurements for a single execution of the quantum program, and a collection of bitstrings from multiple shots may be analyzed to compute quantum state probabilities.

In some implementations, the controllers 106A include one or more clocks that control the timing of operations. For example, operations performed by the controllers 106A may be scheduled for execution over a series of clock cycles, and clock signals from one or more clocks can be used to control the relative timing of each operation or groups of operations. In some implementations, the controllers 106A may include classical computer resources that perform some or all of the operations of the servers 108 described above. For example, the controllers 106A may operate a compiler to generate binary programs (e.g., full or partial binary programs) from source code; the controllers 106A may include an optimizer that performs classical computational tasks of a hybrid classical/quantum program; the controllers 106A may update binary programs (e.g., at runtime) to include new parameters based on an output of the optimizer, etc.

The other quantum computing system 103B and its components (e.g., the quantum processing unit 102B, the signal hardware 104B, and controllers 106B) can be implemented as described above with respect to the quantum computing system 103A; in some cases, the quantum computing system 103B and its components may be implemented or may operate in another manner.

In some implementations, the quantum computing systems 103A, 103B are disparate systems that provide distinct modalities of quantum computation. For example, the computer system 101 may include both an adiabatic quantum computing system and a gate-based quantum computer system. As another example, the computer system 101 may include a superconducting circuit-based quantum computing system and an ion trap-based quantum computer system. In such cases, the computer system 101 may utilize each quantum computing system according to the type of quantum program that is being executed, according to availability or capacity, or based on other considerations.

FIG. 2A includes schematic diagrams showing aspects of example quantum logic circuits 200, 220. In some implementations, the example quantum logic circuits 200, 220 with time proceeding from left to right may include additional and different features or components, and components of the example quantum logic circuits 200, 220 may be implemented in another manner. In certain instances, the example quantum logic circuits 200, 220 may include additional quantum logic operations that can be applied on more qubits implemented by more qubit devices. It is to be appreciated that the measurement results can be fed-forward into the next round of stabilizer checks to, in some cases, improve the performance of the system. In some instances, the example quantum logic circuit 200, 220 may be implemented as part of a surface code, a quantum error correction process, or another process.

As shown in FIG. 2A, the example quantum logic circuits 200, 220 are executed on qubits implemented by five qubit devices, including four data qubit devices 202A, 202B, 202C, 202D and a stabilizer check qubit device 204. Each of the data qubit devices 202A, 202B, 202C, 202D is communicably coupled to the stabilizer check qubit device 204, for example via a tunable-frequency coupler device, a fixed-frequency coupler device, or other types of coupler devices. In some instances, the example quantum logic circuit 200, 220 may be executed by operation of a quantum computing system (e.g., the control system 402 and the superconducting quantum processing unit 404, 500 in FIGS. 4-5).

As shown in FIG. 2A, the example quantum logic circuit 200 includes a sequence of quantum logic operations and is configured for performing a X-check protocol. In some implementations, the X-check protocol represented by the example quantum logic circuit 200 includes a first Hadamard (H) gate 206A applied to a qubit at time t₁, which is implemented by the stabilizer check qubit device 204, for preparing the qubit along the Z-axis of its Bloch sphere. The quantum logic circuit 200 further includes four CNOT gates 208 at time t₂, t₃, t₄, t₅ applied on pairs of qubits implemented by the stabilizer check qubit device 204 and each of the data qubit devices 202A, 202B, 202C, 202D. The quantum logic circuit 200 further includes a second Hadamard gate 206B applied to the qubit implemented by the stabilizer check qubit device 204 at time t₆. The qubits implemented by the data qubit devices 202A, 202B, 202C, 202D and the stabilizer check qubit device 204 are entangled by the application of the four two-qubit CNOT gates 208.

As shown in FIG. 2A, the example quantum logic circuit 220 includes a second sequence of quantum logic operations and is configured for performing a Z-check protocol. In some implementations, the Z-check protocol represented by the quantum logic circuit 220 includes four CNOT gates 222 applied at time t₁, t₂, t₃, t₄, to pairs of qubits implemented by the stabilizer check qubit device 204 and each of the data qubit devices 202A, 202B, 202C, 202D. The qubits implemented by the data qubit devices 202A, 202B, 202C, 202D and the stabilizer check qubit device 204 are entangled by the application of the four two-qubit CNOT gates 222.

FIG. 2B includes schematic diagrams showing aspects of example quantum logic circuits 210, 230. In some implementations, the example quantum logic circuits 210, 230 with time proceeding from left to right may include additional and different features or components, and components of the example quantum logic circuits 210, 230 may be implemented in another manner. It is to be appreciated that the measurement results can be fed-forward into the next round of stabilizer checks to, in some cases, improve the performance of the system. In some instances, the example quantum logic circuit 210, 230 may be implemented as part of a surface code, a quantum error correction process, a syndrome extraction process, or another process.

As shown in FIG. 2B, the example quantum logic circuits 210, 230 are executed on qubits implemented by five qubit devices, including the four data qubit devices 202A, 202B, 202C, 202D and the stabilizer check qubit device 204. In certain instances, the example quantum logic circuits 210, 230 may include additional quantum logic operations that can be applied on more qubits implemented by more qubit devices. Each of the data qubit devices 202A, 202B, 202C, 202D is communicably coupled to the stabilizer check qubit device 204, for example via a tunable-frequency coupler device, a fixed-frequency coupler device, or other types of coupler devices. In some instances, the example quantum logic circuit 210, 230 may be executed by operation of a quantum computing system (e.g., the control system 402 and the quantum processing unit 404, 500 in FIGS. 4-5). For example, the example quantum logic circuits 210, 230 may include more CNOT gates that can be applied to qubits implemented by additional data qubit devices 202 and stabilizer check qubit devices 204.

The quantum logic circuit 210 is logically equivalent to the quantum logic circuit 200 for performing a X-check protocol. In some instances, the quantum logic circuit 210 is obtained by decomposing the CNOT gates 208 in the quantum logic circuit 200. In some implementations, the X-check protocol represented by the quantum logic circuit 210 includes a first set of Hadamard gates 212A applied at time t₁ to the qubits implemented by the stabilizer check qubit device 204 and the data qubit devices 202A, 202B, 202C, 202D. The quantum logic circuit 210 further includes four CZ gates 214 (e.g.,

$${U}_{CZ}^{{⊗}_{4}}$$

applied at t₂, t₃, t₄, t₅ on pairs of the qubits implemented by the stabilizer check qubit device 204 and each of the data qubit devices 202A, 202B, 202C, 202D. The quantum logic circuit 210 further includes a second set of Hadamard gates 212B applied time t₆, to the qubits implemented by the stabilizer check qubit device 204 and the data qubit devices 202A, 202B, 202C, 202D.

The quantum logic circuit 230 is logically equivalent to the quantum logic circuit 220 for performing a Z-check protocol. In some instances, the quantum logic circuit 230 is obtained by decomposing the CNOT gates 222 in the quantum logic circuit 220. In some implementations, the Z-check protocol represented by the quantum logic circuit 230 includes a first Hadamard gate 232A applied at t₁ to the qubit implemented by the stabilizer check qubit device 204. The quantum logic circuit 230 further includes four CZ gates 234 (e.g.,

$${U}_{CZ}^{{⊗}_{4}}$$

applied at time t₂, t₃, t₄, t₅ to pairs of qubits implemented by the stabilizer check qubit device 204 and the data qubit devices 202A, 202B, 202C, 202D. The quantum logic circuit 230 further includes a second Hadamard gate 232B applied at t₆ to the qubit implemented by the stabilizer check qubit device 204.

As shown in FIGS. 2A-2B, each of the quantum logic circuits 200, 220 involves multiple temporal steps: preparation of the stabilizer check qubit device 204 (e.g., the first Hadamard gate 206A, 212A, 232A at time t₁), stabilizer measurements (e.g., the CNOT gates 208, 222 and CZ gates 214, 234 at time t₂, t₃, t₄, t₅), and measurement of the stabilizer check qubit device 204 (e.g., after performing the Hadamard gates 206B, 212B, 232B or after performing the CNOT gates 222). The data qubit devices 202A, 202B, 202C, 202D are idle during the preparation and measurement of the stabilizer check qubit device 204. The stabilizer measurements are based on a sequence of two-qubit quantum logic gates (e.g., CNOT gates 208 222 or CZ gates 214, 234). Standard construction of the surface code revolves around measuring weight-four stabilizers (e.g.,

$${X}^{{⊗}_{4}} and {Z}^{{⊗}_{4}}$$

) on data quibit device 202A, 202B, 202C, 202D via the stabilizer check qubit devices 204. As shown in FIGS. 2A-2B, the CNOT gates 208 222 and the CZ gates 214, 234 in the quantum logic circuits 200, 220, 210, 230 are always applied in a specific order, e.g., forming a zigzag shape, so as to ensure all stabilizer generators commute when measured and ordering of the stabilizer generators does not affect the CNOT gates or the CZ gates. This constraint is lifted when complete cycles of X and then Z parity checks performed alternating in time across the fabric, which is a layout choice made for superconducting hardware given the comparable times between the superconducting quantum processing unit for parity mapping and the projective, quantum nondemolition (QND) measurement.

FIG. 2C is a schematic diagram showing aspects of an example quantum logic circuit 240. In some implementations, the example quantum logic circuit 240 with time proceeding from left to right may include additional and different features or components, and components of the example quantum logic circuit 240 may be implemented in another manner. It is to be appreciated that the measurement results can be fed-forward into the next round of stabilizer checks to, in some cases, improve the performance of the system. In some instances, the example quantum logic circuit 240 may be implemented as part of a surface code, a quantum error correction process, a syndrome extraction process, or another process.

As shown in FIG. 2C, the example quantum logic circuit 240 is executed on qubits implemented by five qubit devices, including the four data qubit devices 202A, 202B, 202C, 202D and the stabilizer check qubit device 204. In certain instances, the example quantum logic circuit 240 may include additional quantum logic operations that can be applied on more qubits implemented by more qubit devices. Each of the data qubit devices 202A, 202B, 202C, 202D is communicably coupled to the stabilizer check qubit device 204, for example via a tunable-frequency coupler device, a fixed-frequency coupler device, or other types of coupler devices. In some instances, the example quantum logic circuit 240 may be executed by operation of a quantum computing system (e.g., the control system 402 and the quantum processing unit 404, 500 in FIGS. 4-5).

As shown in FIG. 2C, the example quantum logic circuit 240 includes a first set of Hadamard gates 242A applied at t₁ to the qubits implemented by the stabilizer check qubit device 204 and the data qubit devices 202A, 202B, 202C, 202D. The example quantum logic circuit 220 further includes a five-qubit Mølmer-Sørensen (MS) gate 244 at time t₂ for phase separation in the stabilizer measurements. The example quantum logic circuit 240 further includes a second set of Hadamard gates 242B applied at time t₃ to the qubits implemented by the stabilizer check qubit device 204 and the data qubit devices 202A, 202B, 202C, 202D.

The example quantum logic circuit 240 is quantum-logically equivalent to the four CZ gates 214, 234 of the quantum logic circuits 210, 230 in FIG. 2B up to single-qubit phase gates applied to the qubits implemented by the data qubit devices 202A, 202B, 202C, 202D. In some implementations, the quantum logic circuit 240 can be formed by compiling the

$${U}_{CZ}^{{⊗}_{4}}$$

gate 214, 434 of the quantum logic circuit 210, 230 in FIG. 2B. In some instances, a multi-qubit MS gate can be used to generate an effective interaction having a Hamiltonian interaction defined as:

$$H = g {\sum }_{i \neq j} {X}_{i} {X}_{j} \qquad ( 1 )$$

where g is an interaction strength that depends on system parameters, and Xᵢ, Xⱼ are the Pauli-X operators on the i-th or j-th qubit, and the sum is over the coupled qubit devices (i≠j). To realize a single-step compilation of the equivalent

$${U}_{CZ}^{{⊗}_{4}}$$

gate 214, 234 in FIG. 2B, the interaction among the five qubit devices is evolved for a calibrated time to achieve a unitary of the form defined below:

$$X {X}_{N} ( θ ) = {e}^{- i {Σ}_{i \neq j} \frac{{θ}_{i j}}{2} {X}_{i} {X}_{j}} \qquad ( 2 )$$

where N is the number of qubits in the multi-qubit system, N is an integer and N ≥2. When N=5, the MS gate is applied to a five-qubit system; and at the special angle θ=π/4, the example quantum logic circuit 240 (e.g., the first Hadamard gates 242A, the XX₅ (π/4) gate, and the second Hadamard gates 242B) is further equivalent to the CZ gates 214, 234 in FIG. 2B. The qubits in the five-qubit system are evolved under the interaction Hamiltonian defined in equation (1) to accumulate the desired phase. In some implementations, the quantum logic circuit 240 based on multi-qubit MS gate can provide advantages. For example, a constant rate of error can be obtained using the quantum logic circuit 240 based on the five-qubit MS gate, e.g., XX₅ (π/4) gate, for a stabilizer measurement, which can outperform the quantum logic circuits 200, 220 based on CNOT gates and the quantum logic circuits 210, 230 based on CZ gates. For another example, the effective error correction threshold can be increased, e.g., by \sqrt{5/2}; and for a fixed distance code, the stabilizer measurement based on the five-qubit MS gate can create lower logical qubit error compared to its equivalent CNOT gates or CZ gates shown in FIGS. 2A-2B. In some instances, other advantages may be obtained using the multi-qubit MS gate.

FIG. 2D is a schematic diagram showing aspects of an example quantum logic circuit 250. In some implementations, the example quantum logic circuit 250 with time proceeding from left to right may include additional and different features or components, and components of the example quantum logic circuit 250 may be implemented in another manner. It is to be appreciated that the measurement results can be fed-forward into the next round of stabilizer checks to, in some cases, improve the performance of the system. In some instances, the example quantum logic circuit 250 may be implemented as part of a surface code, a quantum error correction process, a syndrome extraction process, or another process.

As shown in FIG. 2D, the example quantum logic circuit 250 is executed on qubits implemented by five qubit devices, including the four data qubit devices 202A, 202B, 202C, 202D and the stabilizer check qubit device 204. In certain instances, the example quantum logic circuit 250 may include additional quantum logic operations that can be applied on more qubits implemented by more qubit devices. Each of the data qubit devices 202A, 202B, 202C, 202D is communicably coupled to the stabilizer check qubit device 204, for example via a tunable-frequency coupler device, a fixed-frequency coupler device, or other types of coupler devices. In some instances, the example quantum logic circuit 250 may be executed by operation of a quantum processing unit (e.g., the superconducting quantum processing unit 400, 500 in FIGS. 4-5).

As shown in FIG. 2D, the example quantum logic circuit 250 includes a five-qubit dispersive ZZ gate 252 for phase separation during a stabilizer measurement. The five-qubit dispersive ZZ gate 252 is equivalent to the

$${U}_{CZ}^{{⊗}_{4}}$$

gates 214, 234 or the quantum logic circuits 210, 230 in FIG. 2B up to single-qubit phase gates applied to the qubits implemented by the data qubit devices 202.

In some implementations, the quantum logic circuit 250 can be formed by compiling the

$${U}_{CZ}^{{⊗}_{4}}$$

gates 214, 234 of the quantum logic circuit 210, 230 in FIG. 2B. In some instances, an N-qubit dispersive ZZ gate can be used to generate the effective interaction Hamiltonian interaction defined below:

$$H = χ {\sum }_{k = 1}^{N} {Z}_{0} {Z}_{k} \qquad ( 3 )$$

where N is the number of qubits in the multi-qubit system, N is an integer and N ≥2, x is the dispersive interaction strength, Z₀ and Zₖ are Pauli-Z operators applied on the stabilizer check qubit device and the k-th data qubit devices, k is an integer, and k=1, 2, . . . . N. The Hamiltonian can be evolved in a time t to realize the unitary:

$$Z {Z}_{N} ( θ ) = {e}^{- i θ {Σ}_{k = 1}^{N} {Z}_{0} {Z}_{k}} \qquad ( 4 )$$

with θ=χτ. When N=5, the five-qubit dispersive ZZ gate 252 applied on qubits implemented by the stabilizer check qubit device 204 and the four data qubit device 202A, 202B, 202C, 202D. shown in FIG. 2D, at the special angle θ=π/4, is quantum-logically equivalent to the CZ gates 214, 234 in FIG. 2B:

$${U}_{CZ}^{{⊗}_{4}} = \sqrt{i} Z {Z}_{2} ( - \frac{π}{4} ) [ I ⊗ {Z}_{π / 2}^{0} ⊗ {Z}_{π / 2}^{1} ⊗ {Z}_{π / 2}^{2} ⊗ {Z}_{π / 2}^{3} ] \qquad ( 5 )$$

where the identity gate (I) on the right-hand side of the equation (5) is applied to the qubit implemented by the stabilizer check qubit device 204.

To implement a four-qubit parity check, the dispersive interaction between the stabilizer check qubit device 204 and the data qubit devices 202 can be used,

$$H = χ {a}_{s}^{†} {a}_{s} ( {a}_{0}^{†} {a}_{0} + {a}_{1}^{†} {a}_{1} + {a}_{2}^{†} {a}_{2} + {a}_{3}^{†} {a}_{3} ) \qquad ( 6 )$$

where as

$${a}_{s}^{†} {a}_{s}$$

is the annihilation (creation) operator for the stabilizer qubit, and

$${a}_{i}^{†} {a}_{i} , i ∈$$

{0, 1, 2, 3} is the annihilation (creation) operator for the data qubit devices 202A, 202B, 202C, 202D. The parity of the photon number can be mapped onto the transmon state by initializing the transmon in the ground state; and performing two χπ/2 gates, separated by a waiting time equal to τ=π/χ in which a conditional phase accumulates, separating even and odd photon numbers. The interaction in equation (6), evolved for χτ=π, is equivalent to the

$${U}_{CZ}^{{⊗}_{4}}$$

gates 214, 234 in FIG. 2B up to single qubit phases, with the notable property that this interaction is implemented using a single five-qubit quantum logic gate. χ=2π×0.8 MHz.

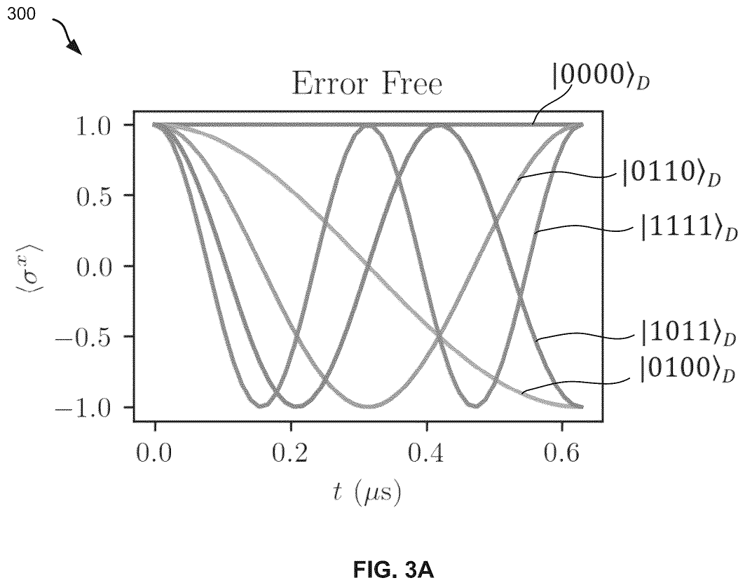

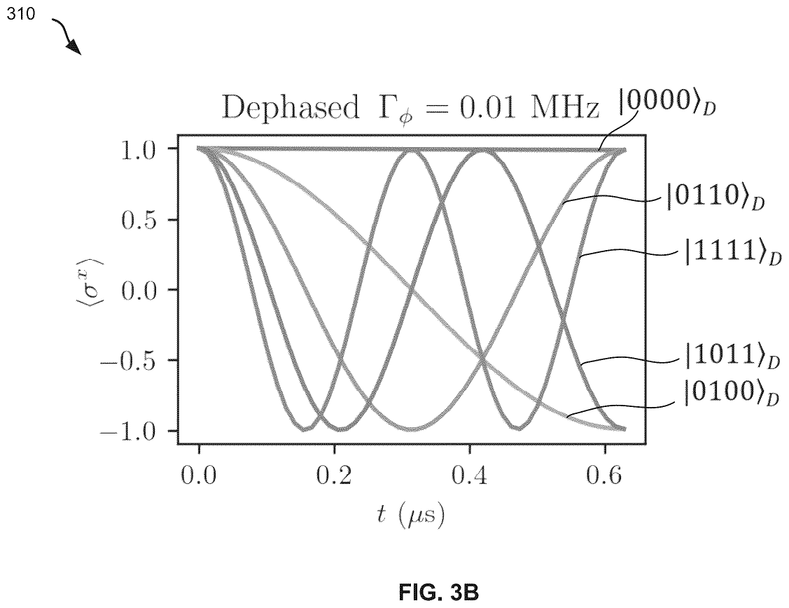

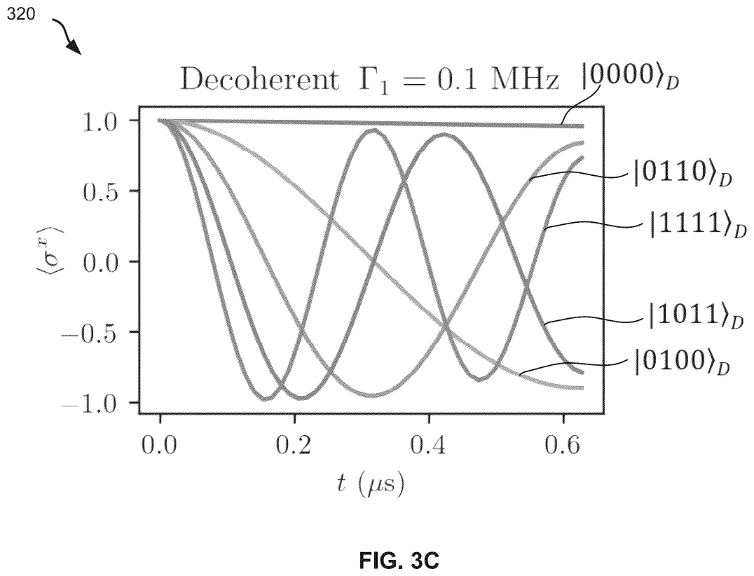

FIG. 3A is a plot 300 showing the [symbol] σ^{x} [symbol] value of the stabilizer check qubit device 204 in a range of 1 and −1 as a function of time in microseconds (μs) without a presence of error (error-free) for different cases of parity in the data qubit devices 202A, 202B, 202C, 202D in FIG. 2D.

FIG. 3B is a plot 310 showing the [symbol] σ^{x} [symbol] value in a range of 1 and −1 as a function of time in microseconds (μs) with a presence of dephasing (Γ_{ϕ}=0.01 MHz) for different cases of parity in the data qubit devices 202A, 202B, 202C, 202D in FIG. 2D.

FIG. 3C is a plot 320 showing the [symbol] σ^{x} [symbol] value in a range of 1 and −1 as a function of time in microseconds (μs) with a presence of decoherence (dephasing and energy loss, Γ₁=0.1 MHz) for different cases of parity in the data qubit devices 202A, 202B, 202C, 202D in FIG. 2D.

Evolution for the stabilizer state of the stabilizer check qubit device 204 is shown in FIGS. 3A-3C, where the stabilizer check qubit device 204 is in the X-basis, and the data qubit devices 202A, 202B, 202C, 202D are in different permutations of excited state even- and odd-parity, e.g.,

$${{{{{\vert 0000 〉}_{D} , \vert 0100 〉}_{D} , \vert 0110 〉}_{D} , \vert 1011 〉}_{D} , \vert 1111 〉}_{D} \qquad ( 7 )$$

The evolution of the stabilizer state (initialized in the X-basis) of the stabilizer check qubit device 204 depends on the parity of the data qubit devices 202A, 202B, 202C, 202D. As shown in FIG. 3A, the final state of the stabilizer check qubit device 204 at the end of the operation for chosen parameters, which gives [symbol] σ^{z} [symbol] =+1 for an even number of the data qubit devices 202A, 202B, 202C, 202D at an excited state (e.g., |0100 [symbol] _{D}, |1011 [symbol] _{D}) and [symbol] ^{z} [symbol] =−1 for an odd number of the data qubit devices 202A, 202B, 202C, 202D at an excited state (e.g., |0000 [symbol] _{D}, |0110 [symbol] _{D′}, |1111 [symbol] _{D}), enabling a single-operation stabilizer measurement on all four data qubit devices 202A, 202B, 202C, 202D. As shown in FIG. 3B, degradation in the final states of the stabilizer check qubit device 204 with a presence of dephasing is negligible.

To simulate the decoherence (e.g., unwanted energy loss) in FIG. 3C, collapse operators for the stabilizer check qubit device 204 and the data qubit devices 202A, 202B, 202C, 202D are set as \sqrt{Γ_{ϕ}}σ^{z}(\sqrt{Γ₁}σ₋). In the presence of significant energy loss, this method gives a reliable measurement of the parity of the data qubit devices 202A, 202B, 202C, 202D, with the most error occurring for the |1111 [symbol] _{D} case with an expectation value [symbol] σ^{z} [symbol] ≈0.73 at the end of the operation for chosen parameters.

In some instances, improvements in error correction behavior can be achieved. For example, a superposition of the states {|0 [symbol] , |2 [symbol] } can be used. Furthermore, lower noise operation can be achieved by incorporating dynamical decoupling operation into the quantum logic circuits. For example, when a data qubit device is connected to multiple stabilizer check qubit devices, the ZZ coupling between the data qubit device and at least one of the multiple stabilizer check qubit devices can be deactivated. Furthermore, pulse shaping can be used to achieve faster parity mapping operations using number-selective single-qubit rotations on the stabilizer check qubit devices 204.

FIG. 4 is a schematic diagram showing aspects of an example quantum computing system 400. The example quantum computing system 400 shown in FIG. 4 may be deployed as one or more of the quantum computing systems (e.g., 103A, 103B) shown in FIG. 1, or the quantum computing system 400 may be deployed in another type of computing environment. As shown in FIG. 4, the example quantum computing system 400 includes a control system 402 and a quantum processing unit 404. The example quantum processing unit 404 may be implemented as the quantum processing unit 102 in FIG. 1. The example quantum computing system 400 may include additional or different features, and the components may be arranged in another manner.

In some instances, the quantum processing unit 404 is a superconducting quantum processing unit. In this case, the example quantum processing unit 404 includes a device array, which includes superconducting quantum circuit devices arranged in a two-dimensional layout. Twenty-one of the superconducting quantum circuit devices in the device array are shown in FIG. 4. In particular, the quantum processing unit 404 includes nine qubit devices 412 and twelve coupler devices 414. The qubit devices 412 may be implemented as tunable-frequency transmon qubit devices, flux qubit devices, flatsonium qubit devices, fluxonium qubit devices, or other types of qubit devices. The qubit devices 412 may be implemented as fixed-frequency qubit devices or tunable-frequency qubit devices. The coupler devices 414 may be implemented as fixed-frequency coupler devices, tunable-frequency coupler devices, LC resonator devices, or other types of coupler devices. In some implementations, the quantum processing unit 404 shown in FIG. 4 is part (e.g., a two-dimensional grid on one layer) of a three-dimensional lattice, which includes multiple layers of two-dimensional grids shown in FIG. 4. A coupling between two qubit devices from two distinct layers may be achieved by a static capacitive fixed-frequency coupling, a tunable-frequency coupling, or other types of coupling.

In the example shown in FIG. 4, the quantum circuit devices are arranged in a rectilinear (e.g., rectangular or square) array that extends in two spatial dimensions (in the plane of the page), and each qubit device 412 is communicably coupled with four other nearest-neighbor qubit devices 412 through a respective coupler device 414. For example, the qubit device 412B is coupled with qubit devices 412A and 412C through respective coupler devices 414A and 414B and qubit device 412A is also coupled with qubit device 412D through a coupler device 414C. In other words, two coupler devices 414A, 414C, are associated with the qubit device 412A. In some instances, the qubit device 412A may be coupled with other qubit devices in the same layer or in different layers. In some instances, more coupler devices 414 may be associated with a qubit device 412. For example, four coupler devices 414D, 414F, 414I, and 414G are associated with the qubit device 412E. In some implementations, the quantum circuit devices in the quantum processing unit 404 can be arranged in another type of ordered array. In some instances, the rectilinear array also extends in a third spatial dimension (in/out of the page), for example, to form a cubic array or another type of three-dimensional array. In this case, a qubit device may have a higher connectivity according to the number of the associated coupler devices. For example, the qubit device 412E may include additional coupler devices configured to provide coupling with other qubit devices residing at different layers of a three-dimensional lattice.

In some aspects, parametrically activated quantum logic gates are supported in a two-dimensional or three-dimensional architecture (e.g., an architecture where quantum circuit devices are distributed over two or three spatial dimensions). For instance, the positions of the qubit devices within the example quantum processing unit 404 may define one or more two-dimensional spatial arrays in a plane, and readout resonators associated with the qubit devices can be positioned within another plane (e.g., on another processor substrate). In some cases, qubit devices 412 on one substrate 408 are electronically coupled to readout resonators on another substrate through conductive signal vias, interconnections, cap wafers, or other types of structures. Accordingly, frequency allocation schemes can be defined for two-dimensional and three-dimensional processor architectures.

In some implementations, the control system 402 interfaces with the quantum processing unit 404 through signal hardware that includes control lines 406. The control system 402 and control lines 406 may be implemented, for example, as described with respect to the controller 106 and the signal hardware 104 of the example control system 105 shown in FIG. 1, or in another manner.

In the example quantum processing unit 404 shown in FIG. 4, each of the qubit devices 412 can be encoded with a single bit of quantum information (a qubit). Each of the qubit devices has two eigenstates that are used as computational basis states, and each qubit device can transition between its computational basis states or exist in an arbitrary superposition of its computational basis states. In some examples, a multi-level quantum system, e.g., a qudit, may be a two-level quantum system which includes two lowest energy levels (e.g., the ground state |0 [symbol] and a first excited state |1 [symbol] ) used as computational basis states for quantum computation. In some examples, a multi-level quantum system includes higher energy levels (e.g., a second excited state |2 [symbol] or a third excited state |3 [symbol] used as computational basis states for quantum computation in some instances.

In some implementations, the qubits of the respective qubit devices can be manipulated by control signals generated or read by readout signals received by the control system 402. The qubit devices 412 can be controlled individually, for example, by communicating control signals to the respective qubit devices. In some cases, a coupler device 414 may be a tunable-frequency coupler device. In this case, the coupling between two qubit devices can be activated or deactivated by tuning the transition frequency of the associated tunable-frequency coupler device. Control signals can be communicated to the qubit devices and the associated tunable-frequency coupler device. In some implementations, associated tunable-frequency coupler devices include those that are in the same layer or between different layers in a three-dimensional lattice. In some cases, readout devices can detect the qubits of the qubit devices, for example, by interacting directly with the respective qubit devices.

In some examples, a tunable-frequency qubit device includes a superconducting circuit loop (e.g., a SQUID loop) that receives a magnetic flux which can tune the transition frequency of the tunable-frequency qubit device. In some instances, the transition frequency can be tuned within a range of frequencies (e.g., between a maximum transition frequency and a minimum transition frequency). The superconducting circuit loop may include two Josephson junctions, and the tunable-frequency qubit device may also include a shunt capacitor connected in parallel with each of the two Josephson junctions. In certain instances, the energy difference E between any two adjacent energy levels in a qubit device can be represented as a transition frequency ω of the qubit device (e.g., according to ω=E/ℏ). In some examples, a transition frequency is tunable, for example, by application of a magnetic flux. In this case, the transition frequency may be defined at least in part by Josephson energies of the two Josephson junctions, a capacitance of the shunt capacitor, and a magnetic flux threading the superconducting circuit loop. A qubit operating frequency of the tunable-frequency qubit device is a transition frequency at which the tunable-frequency qubit device operates.

In the example shown in FIG. 4, each qubit device 412 has one or more tunable transition frequencies. In some cases, the transition frequencies of the tunable-frequency qubit devices can be tuned by applying respective offset fields to the respective tunable-frequency qubit devices. Each of the offset fields can be, for example, a magnetic flux bias, a DC electrical voltage, or another type of field.

In some instances, information is encoded in the qubit devices 412 in the quantum processing unit 404, and the information can be processed by operation of the qubit devices 412. For instance, input information can be encoded in the computational states or computational subspaces implemented by some or all of the qubit devices in the quantum processing unit 404. The information can be processed, for example, by applying a quantum program or other operations to the input information. The quantum program may be decomposed as a sequence of native quantum logic gates or instruction sets that are executed by quantum circuit devices in the quantum processing unit 404 over a series of clock cycles. In some cases, information is processed in another manner. Processing the information encoded in the qubit devices can produce output information that can be extracted from the qubit devices. The output information can be extracted, for example, by performing state tomography or individual readout operations. In some instances, the output information is extracted over multiple clock cycles or in parallel with the processing operations.

As shown in FIG. 4, the control system 402 is coupled to each of the superconducting quantum circuit devices (e.g., the qubit devices 412, the coupler devices 414, and other superconducting quantum circuit devices) in the quantum processing unit 404 through the control lines 406. For example, the control system 402 may communicate control signals to and receive readout signals from the quantum processing unit 404. The control signals communicated from the control system 402 to the qubit devices 412 can be configured to modulate, increase, decrease, or otherwise manipulate the qubit operating frequencies of the qubit devices 412. For example, a control signal may include a flux bias signal to tune the transition frequency of the tunable-frequency qubit device. For another example, a control signal may include a flux modulation signal that modulates a magnetic flux experienced by the tunable-frequency qubit device, and thus the transition frequency of the tunable-frequency qubit device. In some implementations, a control signal can be a direct current (DC) signal, an alternating current (AC) signal (e.g., superposed with a DC signal) communicated from the control system 402 to a qubit device 412. Other types of control signals may be used.

In some cases, the control lines 406 may include a flux bias device or another type of flux bias element that is inductively coupled to the superconducting circuit loop of a tunable-frequency qubit device to control the magnetic flux through a superconducting circuit loop in the tunable-frequency qubit device. The control signal may cause the flux-bias device to modulate the magnetic flux at a modulation frequency. In some instances, the modulation frequency of the magnetic flux may be the same as the flux modulation frequency ωₘ of the flux modulation signal, or the modulation frequency of the magnetic flux may have a different value.

In some implementations, a transition frequency (ω_{T}) of a tunable-frequency qubit device can be tuned by tuning a magnetic flux threading a superconducting circuit loop in the tunable-frequency qubit device. A magnetic flux can be modulated by communicating a flux modulation signal from the control system 402 to a flux bias element in a flux bias control line. Consequently, the transition frequency ω_{T} of the tunable-frequency qubit device can be modulated. In some instances, a flux modulation signal includes a flux modulation frequency (ωₘ) causing the transition frequency ω_{T} of a tunable-frequency qubit device to oscillate at a harmonic of the flux modulation frequency ωₘ. In some instances, the transition frequency ω_{T} under modulation is in a range of qubit operation frequencies which is defined by a tunability of a tunable-frequency qubit device. In some instances, a control signal may include a qubit drive signal which can drive the transition between two energy states (e.g., between the ground state and the first excited state) causing a population exchange between the ground state and the excited state.

In some implementations, control signals for a tunable-frequency qubit device including a flux modulation signal and a qubit drive signal can be communicated to the tunable-frequency qubit device on two separate control lines, e.g., a flux bias control line and a qubit drive control line. In some instances, the flux bias control line can be inductively coupled to the superconducting circuit loop to control the magnetic flux and thereby control the transition frequencies of the tunable-frequency qubit device. In certain examples, the qubit drive control line can be capacitively coupled to the tunable-frequency qubit device, e.g., through one or more qubit electrodes of the tunable-frequency qubit device. In this case, when a qubit drive signal and a flux modulation signal are communicated to the tunable-frequency qubit device through the respective control lines, a single-qubit quantum logic gate can be applied to a qubit implemented by the tunable-frequency qubit device. In some instances, the flux modulation signal and the qubit drive signal may be communicated on a single control line that is both inductively and capacitively coupled to the tunable-frequency qubit device. In some instances, the transition frequency of the tunable-frequency qubit device or the tunable-frequency coupler device may be controlled in another manner.

In some implementations, the control system 402 (e.g., a gate calibration module), or another type of system associated with the quantum computing system 200, determines gate parameters for applying quantum logic gates in the quantum processing unit 404 by executing a gate calibration process. For example, the gate parameters may be determined by a gate calibration process defined in software, firmware or hardware, or a combination thereof. In some instances, initial values of the gate parameters for applying quantum logic gates of unitary operations in a quantum logic circuit may be selected by the control system 402 or obtained by the control system 402 (e.g., from a user device).

In some implementations, initial values of control parameters of control signals, e.g., the flux bias amplitude, the flux modulation frequency ωₘ, the flux modulation amplitude δω, the duration of the interaction produced by the flux modulation signal, or other control parameters of other control signals are determined based on the device parameters, e.g., transition frequencies, anharmonicities, data from a calibration or other test procedure, or a combination of these, the gate parameters, and other information.

In some cases, the control system 402 may execute a device measurement process, e.g., when the quantum processing unit 404 is first installed for use in the quantum computing system 400, and the device measurement process may be repeated at other times (e.g., as needed, periodically, according to a calibration schedule, etc.). For instance, a device measurement module may execute a measurement process that obtains device parameters of the quantum circuit devices in the quantum processing unit 404. The device parameters may be obtained by the device measurement process, for example, based on measurements of the quantum processing unit 404, based on a circuit specification of the quantum processing unit 404, based on analytical or numerical calculations, or otherwise. The device parameters may include, for example, qubit frequencies (e.g., a tunable range) and an anharmonicity for each tunable-frequency qubit device. In some instances, device parameters of the superconducting quantum circuit devices obtained from the device measurement process may be stored in a database, which can be used for determining initial values of control parameters of control signals to execute quantum logic gates on respective quantum circuit devices in the quantum processing unit 404.

In some implementations, the control system 402, or another type of system associated with the quantum computing system 400, further determines improved or optimal values of the control parameters of the control signals for executing quantum logic gates on respective quantum circuit devices in the quantum processing unit 404. For example, the improved or optimal values of the gate parameters may be determined by performing a hybrid variational quantum algorithm, or other types of quantum algorithm.

In some instances, when a quantum program is defined and received by a computing system, a subset of superconducting quantum circuit devices of the quantum processing unit 404 can be selected for performing the quantum program, for example, by operation of the server 108 of the computing system 101 in FIG. 1. As shown in FIG. 4, quantum circuit devices 412, 414 may be selected for performing a quantum program.

The example quantum processing unit 404 shown in FIG. 4 resides on the top surface of a substrate 408. In certain instances, the substrate 408 may be an elemental semiconductor, for example silicon (Si), germanium (Ge), selenium (Se), tellurium (Te), or another elemental semiconductor. In some instances, the substrate 408 may also include a compound semiconductor such as aluminum oxide (sapphire), silicon carbide (SiC), gallium arsenic (GaAs), indium arsenide (InAs), indium phosphide (InP), silicon germanium (SiGe), silicon germanium carbide (SiGeC), gallium arsenic phosphide (GaAsP), gallium indium phosphide (GaInP), or another compound semiconductor. In some instances, the substrate 408 may also include a superlattice with elemental or compound semiconductor layers. In certain instances, the substrate 408 includes an epitaxial layer. In some examples, the substrate 408 may have an epitaxial layer overlying a bulk semiconductor or may include a semiconductor-on-insulator (SOI) structure.

In some instances, qubit electrodes and the ground plane of quantum circuit devices (e.g., qubit devices and coupler devices) include superconductive materials and can be formed by patterning one or more superconductive (e.g., superconducting metal) layers or other materials on the surface of the substrate 408. In some implementations, each of the one or more superconductive layers include a superconducting metal, such as aluminum (Al), niobium (Nb), tantalum (Ta), titanium (Ti), vanadium (V), tungsten (W), zirconium (Zr), or another superconducting metal. In some implementations, each of the one or more superconductive layers may include a superconducting metal alloy, such as molybdenum-rhenium (Mo/Re), niobium-tin (Nb/Sn), or another superconducting metal alloy. In some implementations, each of the superconductive layers may include a superconducting compound material, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the qubit electrodes and the ground plane may include multilayer superconductor-insulator heterostructures.

In some implementations, the qubit electrodes and the ground plane of the quantum circuit devices are fabricated on the top surface of the substrate 408 and patterned using a microfabrication process or in another manner. For example, the qubit electrodes and the ground plane may be formed by performing at least some of the following fabrication steps: using chemical vapor deposition (CVD), physical vapor deposition (PVD), atomic layer deposition (ALD), spin-on coating, and/or other suitable techniques to deposit respective superconducting layers on the substrate 408; and performing one or more patterning processes (e.g., a lithography process, a dry/wet etching process, a soft/hard baking process, a cleaning process, etc.) to form openings in the respective superconducting layers.

FIG. 5 are schematic diagrams of a top view and a cross-sectional view of an example quantum processing unit 500. The example quantum processing unit 500 includes superconducting quantum circuit devices. As shown in FIG. 5, the superconducting quantum circuit devices in the example quantum processing unit 500 include a first tunable-frequency qubit device 512, a second tunable-frequency qubit device 514, and a tunable-frequency coupler device 516. The example quantum processing unit 500 includes a ground plane surrounding the first and second tunable-frequency qubit devices 512, 514 and the tunable-frequency coupler device 516, and other superconducting quantum circuit devices.

In some examples, the first and second tunable-frequency qubit devices 512, 514 and the tunable-frequency coupler device 516 may be implemented by other types of systems, and the features and components represented in FIG. 5 can be extended in a larger two-dimensional or three-dimensional array of devices. The example quantum processing unit 500 may include additional or different features and components, which may be configured in another manner. For example, the superconducting quantum circuit devices may include respective readout resonator devices associated with the first and second tunable-frequency qubit devices 512, 514 for performing readout operations. For another example, the example quantum processing unit 500 may include control lines (e.g., flux bias control lines and/or XY qubit control lines) for providing control signals (e.g., to activate or deactivate coupling between the first and second tunable-frequency qubit devices 512, 514) and performing multi-qubit quantum logic gates.

Each of the first and second tunable-frequency qubit devices 512, 514 and the tunable-frequency coupler device 516 includes a superconducting circuit loop that has two Josephson junctions connected in parallel. Particularly, the first tunable-frequency qubit device 512 includes a first superconducting circuit loop 532 having two Josephson junctions 542; the second tunable-frequency device 514 includes a second superconducting circuit loop 534 having two Josephson junctions 544; and the tunable-frequency coupler device 516 includes a third superconducting circuit loop 536 having two Josephson junctions 546. In some implementations, each of the first, second, and third superconducting circuit loops 532, 534, and 536 can be inductively coupled to (has a mutual inductance with) a respective control line, which can individually tune a magnetic flux in a respective superconducting circuit loop. The control lines are connected to an external control system (e.g., the control system 105, 402 in FIGS. 1 and 4) which is configured to generate respective flux control signals. The two Josephson junctions in a superconducting circuit loop include an asymmetric Superconducting Quantum Interference Device (SQUID). In some instances, the first and second tunable-frequency qubit devices 512, 514 and the tunable-frequency coupler device 516 may include additional or different features; and may operate as described with respect to FIG. 5 or in another manner. For example, the superconducting circuit loops 532, 534, and 536 may include more than two Josephson junctions.

As shown in FIG. 5, each of the first and second tunable-frequency qubit devices 512, 514 and the tunable-frequency coupler device 516 includes a pair of qubit electrodes. Particularly, the first tunable-frequency qubit device 512 includes a first pair of qubit electrodes 522A/522B; the second tunable-frequency qubit device 514 includes a second pair of qubit electrodes 524A/524B; and the tunable-frequency coupler device 516 includes a third pair of coupler electrodes 526A/526B. Each of the qubit electrodes 522A/522B, 524A/524B and the coupler electrodes 526A/526B are electrically floating at a certain potential without being conductively connected to the ground plane. In other words, since the ground plane are configured around superconducting quantum circuit devices, the qubit electrodes 522A/522B, 524A/524B, and the coupler electrodes 526A/526B are capacitively coupled to the ground plane.

In some examples, a shunt capacitor can be formed between two qubit electrodes from the same superconducting quantum circuit device. As shown in the example equivalent circuit 600 of the example quantum processing unit 500, the shunt capacitors 622, 624, 626 are caused by the two qubit electrodes 522A/522B, 524A/524B, and coupler electrodes 526A/526B in the first and second tunable-frequency qubit devices 602, 604, and the tunable-frequency coupler device 606, respectively. In some instances, a residual capacitor can be formed between two qubit electrodes from two distinct superconducting quantum circuit devices forming a capacitive coupling between the two distinct superconducting quantum circuit devices. As shown in the example equivalent circuit 600 of the example quantum processing unit 500, a residual capacitor can be formed between a coupler electrode of the tunable-frequency coupler device 516 and a qubit electrode of first or second tunable-frequency qubit devices 512, 514. In some instances, a residual capacitor can be formed between a qubit electrode of the first tunable-frequency qubit device 512 and a qubit electrode of the second tunable-frequency qubit device 514. Therefore, a static capacitive coupling (g₁₂) 542C between the first and second tunable-frequency qubit devices 512, 514 includes two components, e.g., a direct capacitive coupling component and an indirect capacitive coupling component. In some instances, the direct capacitive coupling component is caused by the capacitance formed between qubit electrodes 522A/522B of the first tunable-frequency qubit device 512 and qubit electrodes 524A/524B of the second tunable-frequency qubit device 514. In some instances, the indirect capacitive coupling component is a capacitive coupling mediated by the tunable-frequency coupler device 606. The indirect capacitive coupling component (91c 542A and 92c 542B) is caused by the capacitances formed between coupler electrodes 526A/526B of the tunable-frequency coupler device 606 and qubit electrodes 522A/522B/524A/524B of the first and second tunable-frequency qubit devices 602, 604.

The example quantum processing unit 500 shown in FIG. 5 resides on the top surface of a substrate 502. In certain instances, the substrate 502 may be an elemental semiconductor, for example silicon (Si), germanium (Ge), selenium (Se), tellurium (Te), or another elemental semiconductor. In some instances, the substrate 502 may also include a compound semiconductor such as aluminum oxide (sapphire), silicon carbide (SiC), gallium arsenic (GaAs), indium arsenide (InAs), indium phosphide (InP), silicon germanium (SiGe), silicon germanium carbide (SiGeC), gallium arsenic phosphide (GaAsP), gallium indium phosphide (GalnP), or another compound semiconductor. In some instances, the substrate 502 may also include a superlattice with elemental or compound semiconductor layers. In certain instances, the substrate 502 includes an epitaxial layer. In some examples, the substrate 502 may have an epitaxial layer overlying a bulk semiconductor or may include a semiconductor-on-insulator (SOI) structure.

The electrodes 522A, 522B, 524A, 524B, 526A, and 526B and the ground plane include superconductive materials and can be formed by patterning one or more superconductive (e.g., superconducting metal) layers or other materials on the surface of the substrate 502. In some implementations, each of the one or more superconductive layers include a superconducting metal, such as aluminum (Al), niobium (Nb), tantalum (Ta), titanium (Ti), vanadium (V), tungsten (W), zirconium (Zr), or another superconducting metal. In some implementations, each of the one or more superconductive layers may include a superconducting metal alloy, such as molybdenum-rhenium (Mo/Re), niobium-tin (Nb/Sn), or another superconducting metal alloy. In some implementations, each of the superconductive layers may include a superconducting compound material, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the electrodes 522A, 522B, 524A, 524B, 526A, and 526B and the ground plane may include multilayer superconductor-insulator heterostructures.

In some implementations, the electrodes 522A, 522B, 524A, 524B, 526A, and 526B and the ground plane are fabricated on the top surface of the substrate 502 and patterned using a microfabrication process or in another manner. For example, the electrodes 522A, 522B, 524A, 524B, 526A, and 526B and the ground plane may be formed by performing at least some of the following fabrication steps: using chemical vapor deposition (CVD), physical vapor deposition (PVD), atomic layer deposition (ALD), spin-on coating, and/or other suitable techniques to deposit respective superconducting layers on the substrate 502; and performing one or more patterning processes (e.g., a lithography process, a dry/wet etching process, a soft/hard baking process, a cleaning process, etc.) to form openings in the respective superconducting layers.

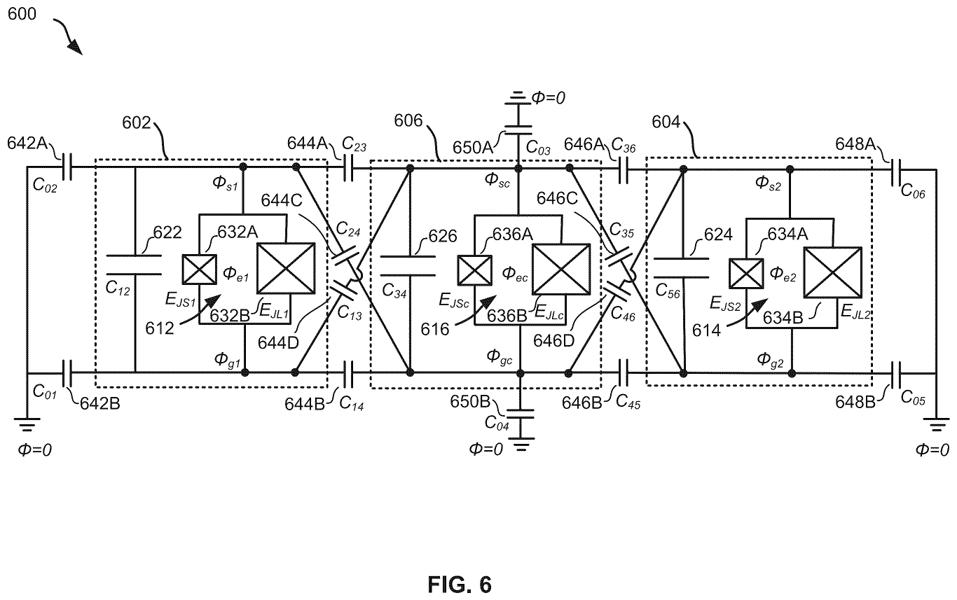

FIG. 6 is a circuit diagram showing an example equivalent circuit 600 of the example quantum processing unit 500 in FIG. 5. The example equivalent circuit 600 represented in FIG. 6 includes a first tunable-frequency qubit device 602, a second tunable-frequency qubit device 604, and a tunable-frequency coupler device 606. For instance, the equivalent circuit 600 in FIG. 6 can represent a pair of qubit devices 412 and the coupler device 414 in the quantum processing unit 404 in FIG. 4, or the equivalent circuit 600 in FIG. 6 can represent devices in another type of system or environment.

As shown, the first tunable-frequency qubit device 602 includes two Josephson junctions, e.g., a first Josephson junction 632A and a second Josephson junction 632B. The first and second Josephson junctions 632A, 632B having Josephson energies E_{JS1} and E_{JL1} are connected in parallel with each other to form a first superconducting circuit loop 612. The first tunable-frequency qubit device 602 also includes a shunt capacitor 622 with a capacitance C₁₂, which is connected in parallel with the two Josephson junctions 632A, 632B. The shunt capacitor 622 is introduced by two qubit electrodes of the first tunable-frequency qubit device 602, e.g., the two qubit electrodes 522A, 522B as shown in the first tunable-frequency qubit device 512 in FIG. 5.

The second tunable-frequency qubit device 604 includes two Josephson junctions, e.g., a third Josephson junction 634A and a fourth Josephson junction 634B. The third and fourth Josephson junctions 634A, 634B having Josephson energies E_{JS2} and E_{JL2} are connected in parallel with each other to form a second superconducting circuit loop 614. The second tunable-frequency qubit device 604 also includes a shunt capacitor 624 with a capacitance C₅₆, which is connected in parallel with the two Josephson junctions 634A, 634B. The shunt capacitor 624 is introduced by two qubit electrodes of the second tunable-frequency qubit device 604, e.g., the two qubit electrodes 524A, 524B as shown in the second tunable-frequency qubit device 514 in FIG. 5.

The tunable-frequency coupler device 606 includes two Josephson junctions, e.g., a fifth Josephson junction 636A and a sixth Josephson junction 636B. The fifth and sixth Josephson junctions 636A, 636B having Josephson energies E_{JSC} and E_{JLC} are connected in parallel with each other to form a third superconducting circuit loop 616. The tunable coupler device 606 also includes a shunt capacitor 626 with a shunt capacitance C₃₄, which is connected in parallel with the two Josephson junctions 636A, 636B. The shunt capacitor 626 is introduced by two electrodes of the tunable-frequency coupler device 606, e.g., the two coupler electrodes 526A, 526B as shown in the tunable-frequency coupler device 516 in FIG. 5.

Each of the first and second tunable-frequency qubit devices 602, 604 and the tunable-frequency coupler device 606 is capacitively coupled to the ground plane (e.g., Φ=0) through respective residual capacitors. Particularly, the first tunable-frequency qubit device 602 is coupled to the ground plane via residual capacitors 642A, 642B having respective capacitances C₀₁ and C₀₂; the second tunable-frequency qubit device 604 is coupled to the ground plane via residual capacitors 648A, 648B having respective capacitances C₀₅ and C₀₆; and the tunable-frequency coupler device 606 is coupled to the ground plane via residual capacitors 650A, 650B having respective capacitances C₀₃ and C₀₄. As shown in FIG. 6, the tunable-frequency coupler device 606 is capacitively coupled to each of the first and second tunable-frequency qubit devices 602, 604 via respective residual capacitors. Particularly, the tunable-frequency coupler device 606 is coupled to the first tunable-frequency qubit device 602 via residual capacitors 644A, 644B, 644C, 644D with respective capacitances C₂₃, C₁₄, C₂₄, and C₁₃; and the tunable-frequency coupler device 606 is coupled to the second tunable-frequency qubit device 604 via residual capacitors 646A, 646B, 646C, 646D with respective capacitances C₃₆, C₄₅, C₃₅, and C₄₆. The residual capacitors are caused by the capacitance between the respective qubit electrodes and coupler electrodes.

In some implementations, control operations can be performed on the circuit 600 by providing control signals to the first and second tunable-frequency qubit devices 602, 604 and the tunable-frequency coupler device 606 via respective control lines. When the two tunable-frequency qubit devices 602, 604 are coupled through the tunable-frequency coupler device 606, the coupling between the two tunable-frequency qubit devices 602, 604 can be activated/deactivated by tuning a magnetic flux applied to the tunable-frequency coupler device 606. For example, a separate control signal (e.g., a DC or an AC current) can be applied to a control line to tune the magnetic flux threading to the third superconducting circuit loop 616 (e.g., the coupler flux bias) of the tunable-frequency coupler device 606 to adjust the transition frequency of the tunable-frequency coupler device 606. When the coupler flux bias is at a parking value, the total coupling strength of a ZZ coupling between the two tunable-frequency qubit devices 602, 604 is effectively, from an operational standpoint, turned off, deactivated, or vanished (e.g., less than or equal to a predetermined threshold value). When the magnetic flux on the tunable-frequency coupler device 606 is at a gate-activating value different from the parking value, the total coupling between the two tunable-frequency qubit devices 602, 604 is effectively, from an operational standpoint, turned on, enabled, or otherwise activated for performing a quantum logic gate.

The Hamiltonian of the tunable-frequency qubit devices 602, 604 and the tunable-frequency coupler device 606 in the system shown in FIG. 6 can be written as

$$H = 4 {E}_{C 1}^{2} {\hat{n}}_{1}^{2} + 4 {E}_{C 2}^{2} {\hat{n}}_{2}^{2} + 4 {E}_{C c}^{2} {\hat{n}}_{c}^{2} + 4 {E}_{12} {\hat{n}}_{1} {\hat{n}}_{2} + 4 {E}_{1 c} {\hat{n}}_{1} {\hat{n}}_{c} + 4 {E}_{2 c} {\hat{n}}_{2} {\hat{n}}_{c} - {\sum }_{k ∈ \{ 1 , 2 , c \}} {E}_{jk} cos ( {\hat{ϕ}}_{km} + {\hat{ϕ}}_{0 k} ) \qquad ( 8 )$$

where nⱼ=Qⱼ/2e is the Cooper pair number operation, E_{Ck} is the charging energy, k∈{1,2, c}, E_{Jk}(ϕₑₖ) is coupling energies given by:

$${E}_{jk} ( {ϕ}_{ek} ) = \sqrt{{E}_{JSk}^{2} + {E}_{JLk}^{2} + 2 {E}_{JSK} {E}_{JSK} cos {ϕ}_{ek}} {ϕ}_{0 k} = {tan}^{- 1} [ \frac{{E}_{JSK} - {E}_{JLK}}{{E}_{JSK} + {E}_{JLK}} tan ( {ϕ}_{ek} / 2 ) ] {n}_{k} = {Q}_{k} / 2 e \qquad ( 9 )$$

where nₖ are Cooper-pair number operators and E_{Ck} are charging energies, E₁₂, E₁ₑ, and E₂ₑ are coupling energies, and E_{JLK} and E_{JSK} are the Josephson energies of the two junctions in the superconducting loops of the qubit devices 602, 604 and the coupler device 606. The reduced fluxes are defined as ϕₗ=2πΦₗ/Φ₀ (l∈{1, 2, . . . 6}) and \hat{ϕ}₁ₘ=\hat{ϕ}₂−\hat{ϕ}₁, \vec{ϕ}₂ₘ=\vec{ϕ}₆−\hat{ϕ}₅, \vec{ϕ}_{cm}=\vec{ϕ}₄−\hat{ϕ}₃ with Φ₀=h/2e being the flux quantum. Numerical modeling and experimental investigation of this Hamiltonian show that by changing the flux biases to the respective superconducting loops 612, 614, 616, the coupling can be adjusted from regions of small dispersive interaction χ<γ (where γ is order the decay rate of the transmon qubits) to regions of strong-dispersive interaction greater than the decay rate, e.g., χ>γ or in another region.

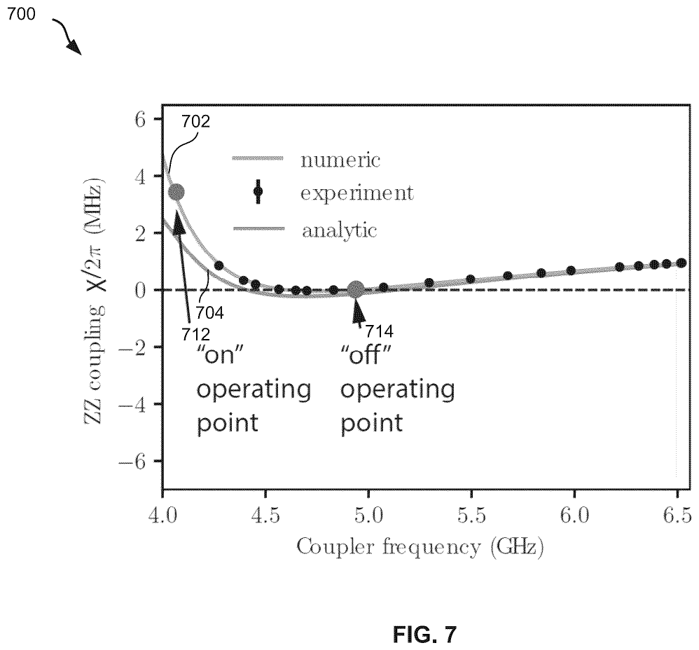

FIG. 7 is a plot 700 showing qubit-qubit ZZ coupling strength (χ/2π) in MHz between the two tunable-frequency qubit devices 512, 514 as a function of the coupler frequency in GHz of the tunable-frequency coupler device 516 shown in FIG. 5. The dotted points are experimentally measured values and the solid curve 702 represents the values of the ZZ coupling strength calculated numerically by diagonalizing the corresponding Hamiltonian constructed using measured device parameters. The solid curve 704 represents the values approximate analytical expression for the ZZ coupling strength. Two points 712, 714 are identified with suitable behavior for activating the requisite interaction/coupling e.g., “on”, and deactivating the interaction/coupling, e.g., “off”.

In some implementations, during the application of the multi-qubit ZZ gate (e.g., ZZ₅(θ)) for stabilizer measurement, the coupler flux bias received at the tunable-frequency coupler devices are at their respective gate-activating values and the interactions between the pairs of qubit devices are activated. In particular, during the application of the multi-qubit ZZ₅(θ) gate as shown in FIG. 2D on qubits implemented by the qubit devices 412B, 412D, 412H, 412F, 412E of the superconducting quantum processing unit 404 in FIG. 4, coupler flux bias for controlling the tunable-frequency coupler devices 414D, 414F, 414I, 414G and thus, the couplings between each of the data qubit devices 412B, 412D, 412H, 412F and the stabilizer check qubit devices 412E are tuned to the respective gate activating values. Before the application of the multi-qubit ZZ₅(θ) gate, for example during the step of preparing the stabilizer check qubit device 412E, the flux bias signals for controlling the tunable-frequency coupler devices 414D, 414F, 414I, 414G for decoupling the data qubit devices 412B, 412D, 412H, 412F from the stabilizer check qubit devices 412E are tuned to the respective parking values. Similarly, after the application of the multi-qubit ZZ₅(θ) gate, for example during the step of measuring the stabilizer check qubit device 412E, the flux bias signals for controlling the tunable-frequency coupler devices 414D, 414F, 414I, 414G for decoupling the data qubit devices 412B, 412D, 412H, 412F from the stabilizer check qubit devices 412E are also tuned to the respective parking values.

In some implementations, when a data qubit device is also coupled to multiple other stabilizer check qubit devices through multiple other tunable-frequency coupler devices, flux bias signals for controlling the multiple other tunable-frequency coupler devices may be also tuned to respective parking values to decouple the data qubit device from the multiple other stabilizer check qubit devices. For example, when the qubit device 412A may be also a stabilizer check qubit device and during the application of the multi-qubit ZZ₅(θ) gate as shown in FIG. 2D on qubits implemented by the qubit devices 412B, 412D, 412H, 412F, 412E of the superconducting quantum processing unit 404 in FIG. 4, the tunable-frequency coupler devices 414A, 414C are deactivated to effectively decouple or isolate the data qubit device 412D, 412B from the stabilizer check qubit device 412A.

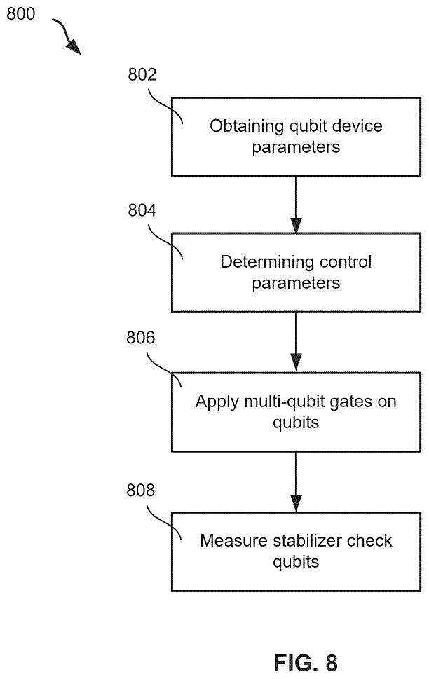

FIG. 8 is a flow chart showing aspects of an example process 800 for performing a multi-qubit stabilizer measurement. The example process 800 can be used, for example, to operate a quantum computing system, e.g., the quantum computing system 400 in FIG. 4. For instance, the example process 800 can be used to perform a single-step stabilizer measurement by executing a multi-qubit quantum logic gates. In certain instances, the example process 800 can be used for determining control parameters of control signals applied to quantum circuit devices in a quantum processing unit where the quantum program is executed. The example process 800 may include additional or different operations, including operations performed by additional or different quantum circuit devices, and the operations may be performed in the order shown or in another order.

In some implementations, one or more operations in the example process 800 can be performed by a computer system, for instance, by a digital computer system having one or more digital processors (e.g., a microprocessor or other data processing apparatus) that execute instructions (e.g., instructions stored in a digital memory or other computer-readable medium), or by another type of digital, quantum or hybrid computer system. As an example, in some cases the quantum processing unit can be deployed as the quantum processing unit 102, 404, 500 shown in FIGS. 1, 4, 5 and operations in the example process 800 shown in FIG. 8 can be initiated, executed, or controlled by one or more components of the control system 105, 402 shown in FIGS. 1, 4.

At 802, device parameters are obtained. In some instances, device parameters of the quantum circuit devices of a quantum processing unit, where a stabilizer measurement is performed, can be obtained. In some implementations, the device parameters of the tunable-frequency qubit devices 512, 514, and the tunable-frequency coupler device 516 in the quantum processing unit 500 are determined by performing a measurement or characterization process, a tune-up process, or another type of calibration process. In some instances, a measurement process can characterize a particular set of quantum circuit devices in the quantum processing unit for performing the stabilizer measurement. In some instances, the device parameters may be predetermined using another process, which then can be stored and obtained in another manner. For example, a measurement process can be executed to characterize all the quantum circuit devices in a quantum processing unit to obtain the device parameters of each of the qubit devices and coupler devices in a device array, for example, once a quantum processor is cooled down.

In some instances, device parameters that can be used to characterize a tunable-frequency qubit device include a tunable range of transition frequencies. In certain examples, a tunable range of transition frequencies is defined by a maximal frequency value, e.g., the |0 [symbol] →|1 [symbol] transition frequency value at a magnetic flux of zero flux quantum applied to the tunable-frequency qubit device,

$${ω}_{01} ( Φ = 0 ) ≡ {ω}_{01}^{max} \qquad ( 10 )$$

and a minimum frequency value, e.g., the |0 [symbol] →|1 [symbol] transition frequency value at a magnetic flux of half-flux quantum,

$${ω}_{01} ( Φ = \frac{{Φ}_{0}}{2} ) ≡ {ω}_{01}^{min} \qquad ( 11 )$$

anharmonicity at the magnetic flux of zero flux quantum,

$$η ( Φ = 0 ) ≡ {η}^{max} \qquad ( 12 )$$

and the qubit flux bias Φ, e.g.,

$$Q = Q ( {ω}_{01}^{max} , {ω}_{01}^{min} , {η}^{max} , Φ ) \qquad ( 13 )$$

where Q represents a collection of device parameters that can be used to describe a qubit device. In some implementations, a maximal frequency value may be at a different magnetic flux. For example, a maximal frequency value may be at a value offset from a magnetic flux of zero flux quantum, a magnetic flux of half flux quantum, or another value.

In some implementations, the device parameters may include one or more of the device parameters of the tunable-frequency qubit device in the quantum processing unit. For example, device parameters, such as a maximum transition frequency

$${ω}_{12}^{max} ,$$

and the anharmonicity (η) at

$${ω}_{12}^{max} ,$$

can be used to characterize the qubit implementation beyond the lowest two states. In some instances, device parameters further include periodicity, coupling strengths, and other device parameters can be calibrated, measured, and stored, e.g., in a database of the memory 112 of the server 108. In certain instances, circuit parameters of circuit components in an equivalent circuit representing quantum circuit devices in the quantum processing unit can be calculated based on the device parameters.

In some examples, the transition frequency of a tunable-frequency qubit device or a tunable-frequency coupler device from the ground state |0 [symbol] to the first excited state |1 [symbol] is measured by using qubit spectroscopy. Ramsey interferometry can then be used to fine tune the value of the transition frequency obtained from the spectroscopic measurement. In some instances, the transition frequency can be measured at one or more reference values of the applied magnetic flux. For example, the transition frequency of a tunable-frequency qubit device can be measured at zero flux and one-half flux quantum; the tunable-frequency qubit devices may be measured under other flux conditions.

In some examples, after the transition frequencies of the tunable-frequency qubit device are obtained, qubit spectroscopy can be used to measure the transition frequency from the ground state |0 [symbol] to the second excited state |2 [symbol] which can be used to calculate the anharmonicity of the tunable-frequency qubit device. For instance, the absolute value of the anharmonicity of a tunable-frequency qubit device may be computed as |η|=|2ω₀₁−ω₀₂|, where ω₀₁ represents the transition frequency from the ground state |0 [symbol] to the first excited state |1 [symbol] of the tunable-frequency qubit device, and ω₀₂ represents the transition frequency from the ground state |0 [symbol] to the second excited state |2 [symbol] of the tunable-frequency qubit device.

In some instances, the stabilizer measurement is part of a quantum program for performing a quantum error correction scheme. In some instances, a quantum program may be obtained by performing a compilation operation on a received quantum program from a user (e.g., a user program). A sequence of quantum logic gates in the quantum program before compilation can be converted to a sequence of native quantum logic gates in the quantum program after compilation. In some instances, the sequence of native quantum logic gates can be applied on qubits implemented by qubit devices in the quantum processing unit.

In some implementations, a quantum program can be represented, for example, as a quantum Hamiltonian, a sequence of quantum logic gates, a set of quantum machine instructions, or otherwise. The quantum program may correspond to a computational task, a hardware test, a quantum error correction procedure, a quantum state distillation procedure, or a combination of these and other types of operations. In some instances, a quantum program includes a first sequence of quantum logic gates, e.g., single-qubit quantum logic gates, two-qubit quantum logic gates, multi-qubit quantum logic gates, identity gates, and other quantum logic gates. In some instances, the quantum program can be an Quil program generated by a user device (e.g., the user device 110 as shown in FIG. 1), another computer resource outside the local environment of the quantum computer system 103, or in another manner; and received by a quantum computing system (e.g., the control system 105 of the quantum computing system 103 in FIG. 1).

In some instances, the received quantum program can be compiled. In some implementations, the received quantum program is compiled according to the particular quantum computing system where the quantum program is to be executed. In this case, after compilation, the quantum program includes quantum logic gates that can be executed on quantum circuit devices in a quantum processing unit (e.g., the qubit devices 412 and the associated tunable-frequency coupler devices 414 in the quantum processing unit 404 as shown in FIG. 4). In some implementations, the quantum program can be compiled by operation of a compiler after receiving the quantum program.

In some instances, a native gate set includes a set of quantum logic gates that can be directly executed by the quantum processing unit. After a native gate set for the quantum processing unit is identified, a quantum logic gate in the first sequence of quantum logic gates (e.g., one or more parametric quantum logic gates) in the received quantum program can be converted, translated, or otherwise compiled into a native gate sequence in a second sequence of quantum logic gates. Each of the native quantum logic gates in a native gate sequence may be a parametric single-qubit rotation gate, a parametric two-qubit quantum logic gate, a parametric three-qubit quantum logic gate, or another quantum logic gate. For example, a two-qubit quantum logic gate, e.g., CNOT gate, in a received quantum program from a user can be decomposed into several iSWAP gates or a CZ gate that can be directly executed on quantum circuit devices in a quantum processing unit. In addition to the parametric quantum logic gates, a native gate set may include one or more non-parametric quantum logic gates.

When the quantum program before compilation includes more than one quantum logic gates, more than one native gate sequences can be formed, e.g., by parametric decomposition or in another manner. Generally, the one or more native gate sequences are quantum-logically equivalent to the respective one or more quantum logic gates in the quantum program before compilation.

In some instances, the quantum program after compilation can be further modified. For example, when the second sequence of quantum logic gates includes one or more sub-sequences of CNOT gates (e.g., the CNOT gates 208, 222) or one or more sub-sequences of CZ gates (e.g., the CZ gates 214, 234) applied on qubits implemented by qubit devices as shown in FIGS. 2A-2B, each of the one or more sub-sequences of CNOT gates or CZ gates may be rearranged and reorganized in to a multi-qubit quantum logic gates (e.g., the multi-qubit quantum logic gate 252 as shown in FIG. 2D). For example, the compiler may recognize patterns of quantum logic gates in the second sequence and may apply the conversion of the CZ or CNOT gates into multi-qubit quantum logic gates for performing the multi-qubit stabilizer measurements.

In some instances, when a quantum program for performing an error correction scheme on a quantum processing unit is formed, a multi-qubit quantum logic gate (e.g., the multi-qubit quantum logic gate 252 as shown in FIG. 2D) can be directly selected, e.g., from available quantum logic gates stored in the memory 112 according to the quantum processing unit 102, and included in the quantum program, by operation of the user device 110, the servers 108, or in another manner.

In some instances, a logical qubit can be defined before obtaining the device parameters A logical qubit can be defined based on a number of data qubit devices, error rates, the type of error corrections applied. For example, a logical qubit constructed from a distance five surface code error correction, requires nine data qubit devices and 8 stabilizer check qubit devices. In some instances, the logical qubit is mapped to quantum circuit devices in the quantum processing unit. For example, stabilizer qubit devices and data qubit devices coupled to the stabilizer qubit devices through respective tunable-frequency coupler devices can be selected. In this case, the device parameters of the quantum circuit devices to which the logical qubit is mapped are obtained. In some instances, instructions for defining logical qubits and operations on logical qubits can be determined when the quantum program is compiled.

At 804, control parameters are determined. In some implementations, a calibration process is performed to determine control parameters of control signals for executing the stabilizer measurement on the quantum processing unit. In some implementations, a control signal includes a flux bias signal that can be communicated to the tunable-frequency qubit device on a flux bias control line to tune the transition frequency. In some implementations, a control signal includes a flux modulation signal which can be communicated to the tunable-frequency qubit device on a flux bias control line to modulate the transition frequency. In certain instances, the control signal also includes a drive signal which can be communicated to the tunable-frequency qubit device on a distinct qubit drive control line to activate a single-qubit quantum logic gate. In certain instances, control signals, such as flux modulation signal and qubit drive signal, may be communicated to a qubit device on a common control line which is inductively and capacitively coupled to the qubit device. Control signals (e.g., a flux bias signal, a flux modulation signal, a qubit drive signal or another type of control signal) can be characterized by control parameters of the control signals including modulation parameters such as a DC flux bias Φ_{dc}, a flux modulation amplitude Φ_{ac}, a flux modulation frequency fₘ, a modulation phase θₘ, and drive parameters, such as a drive amplitude Ω_{d}, a drive frequency f_{d}, and a drive phase θ_{d}. In certain examples, the device parameters obtained from the device measurement process can be used to determine initial values of the control parameters of the control signals that can be applied to the respective quantum circuit devices, e.g., to activate a coupling between two qubit devices by tuning the coupler flux bias from a parking value to a gate-activating value, to deactivate a coupling between two qubit devices by tuning the coupler flux bias from a gate-activating value to a parking value, to bring two qubit devices into resonance for a precise time period, and to perform other functions.

In some implementations, a calibration process is performed on quantum circuit devices of a quantum processing unit. In some implementations, a calibration process is performed to determine optimal or improved values of the control parameters of the control signals for executing the operations (e.g., the multi-qubit quantum logic gates and control operations) in the compiled quantum program.

To perform the calibration, the control system of the quantum computing system generates calibration signals, and the calibration signals are delivered to the quantum processing unit of the quantum computing system. The calibration signals can include, for example, microwave pulses applied to individual quantum circuit devices (e.g., qubit devices), flux bias signals applied to individual tunable-frequency coupler devices (e.g., tunable-frequency coupler devices), or other types of signals. The control system then obtains calibration measurements from the quantum processing unit, and the control system uses the calibration measurements to determine the control parameters. For instance, in the quantum computing system 103A shown in FIG. 1, the controllers 106A can identify calibration signals that are configured to execute a pre-defined calibration routine, and the calibration signals can then be generated by the signal hardware 104A and delivered to quantum circuit devices (e.g., qubit devices) in the quantum processing unit 102A. The pre-defined calibration routine can include, for example, the types of experiments, measurements, processes, optimization criteria or other features described in U.S. Pat. No. 10,282,675 entitled “Performing a Calibration Process in a Quantum Computing System;” other types of calibration routines may be used in some cases. During the calibration process, the control system 105A obtains calibration measurements from the quantum processing unit 102A and uses the calibration measurements in the calibration routine, for instance, to identify an improved or optimal value of one or more control parameters. The calibration measurements may include readout signals from readout resonator devices or other types of measurements obtained from the quantum processing unit 104A. The initial values of the control parameters can be modified or otherwise updated based on the calibration measurement results, which may include, for example, the amplitude (power), frequency, duration, or phase of a microwave pulse; the amplitude (power), frequency, duration, or phase of a flux bias signal; or other types of control parameters for control signals.

In some implementations, during a calibration process, calibration signals are generated (e.g., by operation of the control system 402 in FIG. 4) according to values of the control parameters (e.g., the initial values of the control parameters determined based on the device parameters or the improved values determined during the calibration process) and delivered to respective quantum circuit devices of the quantum processing unit (e.g., the qubit devices where native quantum logic gates are executed, the qubit devices where the multi-qubit quantum logic gates are executed, and the associated coupler devices). In order to perform a calibration measurement, calibration signals are communicated to respective quantum circuit devices to perform operations on the respective quantum circuit devices, e.g., tuning the effective coupling strength between two qubit devices, tuning the transition frequency of a tunable-frequency qubit devices, and other operations. In some implementations, results of the calibration measurements are obtained from the quantum processing unit. For example, values of the control parameters of the calibration signals communicated to the respective quantum circuit devices, when the operations for performing the multi-qubit stabilizer measurement are executed in parallel, can be determined. In some implementations, applying the multi-qubit quantum logic gate in a superconducting quantum processing unit includes applying an interaction having a form defined in equation (4).

In some cases, the calibration process may include a continuous-wave (CW) characterization procedure, which may include cavity spectroscopy measurements, qubit spectroscopy measurements, T1 and T2 measurements, and others. In some cases, the calibration process can include a pulsed characterization procedure, which may include cavity spectroscopy measurements, Rabi spectroscopy measurements, Ramsey spectroscopy measurements, power Rabi measurements, T1 and T2 measurements, and others. The CW or pulsed characterization procedures may perform measurements to detect the quality factor, resonance frequency, Lamb shift and other parameters of a device.

In some cases, the calibration process includes a gate tune-up procedure. For example, the gate tune-up procedure may include optimization of readout pulses or parameters, AC Stark coefficient measurements, pi-pulse amplitude tune-ups, Derivative Removal by Adiabatic Gate (DRAG) tune-ups, randomized benchmarking, other types of benchmarking, and others. The gate tune-up may include measurement of coupling strengths between qubit devices, characterization of tuning pulses for tunable-frequency qubit devices, and other types of measurements. In some cases, the calibration process performed includes a tune-up of multi-qubit quantum logic gates, single-qubit quantum logic gates, benchmarking procedures, or other types of processes.

At 806, the multi-qubit quantum logic gate is applied. When the compiled quantum program is executed, the multi-qubit quantum logic gate is applied to qubits implemented by the selected qubit devices for stabilizer measurement. When the multi-qubit quantum logic gate is applied, the stabilizer check qubit device and the data qubit devices are evolved under an interaction Hamiltonian defined by equations (1)-(4) or defined in another form. In some implementations, the interaction Hamiltonian includes a plurality of terms. Each term corresponds to an interaction between the stabilizer check qubit device and a respective one of the data qubit devices. Each term includes a phase combined with a Pauli operator applied to the stabilizer check qubit device and the Pauli operator applied to the respective data qubit devices. In some implementations, when the multi-qubit quantum logic gate is applied, control signals (e.g., qubit drive signals, qubit flux bias signals, coupler flux bias signals, and other control signals) defined by the control parameters are simultaneously applied to the respective quantum circuit devices. In particular, when a multi-qubit stabilizer measurement is performed on the stabilizer check qubit device 412E which is communicably coupled to four data qubit devices 412B, 412D, 412H and 412F through the respective tunable-frequency coupler devices 414D, 414F, 414I, 414G, respective coupler flux bias having respective gate-activating values (e.g., respective ZZ couplings are at respective maximum values) and received at the respective tunable-frequency coupler devices 414D, 414F, 414I, 414G are applied to bring the data qubit devices 412B, 412D, 412H and 412F in resonance with the stabilizer check qubit device 412E. In some implementations, values of the control parameters of the control signals are the improved or updated values obtained from operation 804, which can be stored in the memory 112. In some implementations, during the application of the multi-qubit quantum logic gate, the four data qubit devices 412B, 412D, 412H and 412F and the stabilizer check qubit device 412E are maintained at their respective idling frequencies, for example at their maximum operating frequencies, e.g., by applying respective magnetic flux signals on the data qubit devices 412B, 412D, 412H and 412F. After the tunable-frequency coupler devices 414D, 414F, 414I, 414G are activated and the ZZ couplings are enabled, the multi-qubit system is allowed to evolve for a time period, e.g., t_{gate}.

In some instances, when the same data qubit device is coupled to two or more stabilizer check qubit devices through two or more respective tunable-frequency coupler devices, only one of the two or more respective tunable-frequency coupler devices is activated so that the coupling between the data qubit device and one of the stabilizer check qubit devices is activated and all the others are deactivated. For example, when the data qubit device 412B is coupled to three stabilizer check qubit devices 412A, 412C, 412E and when the multi-qubit stabilizer measurement is applied on the data qubit devices 412B, 412D, 412H, 412F, and the stabilizer check qubit device 412E, coupler flux bias received the tunable-frequency coupler devices 414A, 414B are at their respective parking values so that the couplings between the data qubit device 412B and the two stabilizer check qubit devices 412A, 412C are deactivated. In some instances, the parking values of the coupler flux bias to deactivate the respective tunable-frequency coupler devices are obtained during the operation 804 in parallel with the multi-qubit quantum logic gate.

At 808, the stabilizer check qubit device is measured. For instance, the states of the stabilizer check qubits in the quantum processing unit can be measured by qubit readout operations, and the measured state information can be stored in a cache or other type of memory system in one or more of the controllers (e.g., the controller 106A in FIG. 1) or in the memory 112 of the server 108. In some cases, the measured state information is subsequently used in the execution of a quantum program, a quantum error correction procedure, a quantum processing unit (QPU) calibration or testing procedure, or another type of quantum process. In some instances, the stabilizer check qubit device can be measured; and the associated error syndrome can be recorded. Individual stabilizer generators are measured non-destructively by coupling the relevant data qubit devices to a single stabilizer check qubit device which is then measured to infer the outcome.

In some instances, after the multi-qubit quantum logic gate is executed and prior to the measurement of the stabilizer check qubit device, the coupler flux bias applied to the tunable-frequency coupler devices 414D, 414F, 414I, 414G are returned to their respective parking values and the ZZ couplings between the stabilizer check qubit device 412E and the data qubit devices 412B, 412D, 412H, 412F are deactivated. In some instances, other operations might be performed prior to the measurement of the stabilizer check qubit device.

Some of the operations described in this specification can be implemented as operations performed by a data processing apparatus on data stored on one or more computer-readable storage devices or received from other sources.

The term “data-processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program, or in multiple coordinated files (e.g., files that store one or more modules, sub programs, or portions of code). A computer program can be deployed to be executed on one computer or on multiple computers that are located at one site or distributed across multiple sites and interconnected by a communication network.

Some of the processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., an FPGA (field programmable gate array) or an ASIC (application specific integrated circuit).

In a general aspect, a method and a system for performing a multi-qubit quantum logic gate in a superconducting quantum processing unit for quantum error correction are presented.

In a first example, a superconducting quantum processing unit includes a stabilizer check qubit device and two or more data qubit devices operably coupled to the stabilizer check qubit device through respective tunable-frequency coupler devices. A method for operating the superconducting quantum processing unit includes applying a multi-qubit quantum logic gate on the stabilizer check qubit device and the two or more data qubit devices of the superconducting quantum processing unit. The multi-qubit quantum logic gate encodes information from the two or more data qubit devices onto the stabilizer check qubit device; and the encoded information is usable by a quantum error correction scheme. Applying the multi-qubit quantum logic gate includes evolving the stabilizer check qubit device and the two or more data qubit devices under an interaction Hamiltonian. The interaction Hamiltonian includes a plurality of terms; and each of the plurality of terms corresponding to an interaction between the stabilizer check qubit device and a respective one of the two or more data qubit devices. Each of the terms includes a phase combined with a Pauli operator applied to the stabilizer check qubit device and the Pauli operator applied to the respective one of the two or more data qubit devices.

Implementations of the first example may include one or more of the following features. The interaction Hamiltonian has a form indicative of at least:

$$H = χ {\sum }_{k = 1}^{n} {σ}_{0}^{i} {σ}_{k}^{i} ,$$

where n represents the number of the two or more data qubit devices, x represents the phase,

$${σ}_{0}^{i}$$

represents the Pauli operator applied to the stabilizer check quibit device,

$${σ}_{k}^{i}$$

represents the Pauli operator applied to the k^{th} data qubit device, and k is an integer. When the Pauli operator is the Pauli-Z operator, the interaction Hamiltonian has a form indicative of at least:

$$H = χ {\sum }_{k = 1}^{n} {Z}_{0} {Z}_{k} .$$

Each of the stabilizer check qubit device, the two or more data qubit devices, and the respective tunable-frequency coupler device is a tunable-frequency transmon qubit device. The quantum error correction scheme is based on a surface error correction code. The method further includes prior to applying the multi-qubit quantum logic gate, obtaining device parameters for the stabilizer check qubit device, the two or more data qubit devices, and the respective tunable-frequency coupler devices of the superconducting quantum processing unit; and determining control parameters for applying the multi-qubit quantum logic gate to the stabilizer check qubit device and the two or more data qubit devices according to the qubit device parameters.

Implementations of the first example may include one or more of the following features. Determining the control parameters includes determining parking values of respective coupler flux biases for flux bias signals to deactivate the respective tunable-frequency coupler devices. The method further includes after applying the multi-qubit quantum logic gate, performing a qubit readout measurement on the stabilizer check qubit device. The method includes prior to performing the qubit readout measurement, applying the coupler flux biases at the parking values to the respective tunable-frequency coupler devices in parallel to deactivate the respective tunable-frequency coupler devices in parallel during a time step such that the stabilizer check qubit device is decoupled to the two or more data qubit devices during the time step.

Implementations of the first example may include one or more of the following features. Determining the control parameters includes determining gate-activating values of respective coupler flux biases for flux bias signals to activate the respective tunable-frequency coupler devices. Applying the multi-qubit quantum logic gate includes applying the coupler flux biases at the gate-activating values to the respective tunable-frequency coupler devices in parallel to activate the respective tunable-frequency coupler devices in parallel during a time step such that the stabilizer check qubit device is coupled to the two or more data qubit devices during the time step. The method includes executing a quantum program. The quantum program includes the multi-qubit quantum logic gate and at least one single-qubit quantum logic gate.

In a second example, a quantum computing system includes a superconducting quantum processing unit and a control system communicably coupled to the superconducting quantum processing unit. The quantum processing unit includes a stabilizer check qubit device and two or more data qubit devices coupled to the stabilizer check qubit device through respective tunable-frequency coupler devices. The control system is operable to perform operations including applying a multi-qubit quantum logic gate on the stabilizer check qubit device and the two or more data qubit devices of the superconducting quantum processing unit. The multi-qubit quantum logic gate encodes information from the two or more data qubit devices onto the stabilizer check qubit device; and the encoded information is usable by a quantum error correction scheme. Applying the multi-qubit quantum logic gate includes evolving the stabilizer check qubit device and the two or more data qubit devices under an interaction Hamiltonian. The interaction Hamiltonian includes a plurality of terms; and each of the plurality of terms corresponding to an interaction between the stabilizer check qubit device and a respective one of the two or more data qubit devices. Each of the terms includes a phase combined with a Pauli operator applied to the stabilizer check qubit device and the Pauli operator applied to the respective one of the two or more data qubit devices.

Implementations of the second example may include one or more of the following features. The interaction Hamiltonian has a form indicative of at least

$$H = χ {\sum }_{k = 1}^{n} {σ}_{0}^{i} {σ}_{k}^{i} ,$$

where n represents the number of the two or more data qubit devices, x represents the phase,

$${σ}_{0}^{i}$$

represents the Pauli operator applied to the stabilizer check qubit device,

$${σ}_{k}^{i}$$

represents the Pauli operator applied to the k^{th} data qubit device, and k is an integer. When the Pauli operator is the Pauli-Z operator, the interaction Hamiltonian has a form indicative of at least:

$$H = χ {\sum }_{k = I}^{n} {Z}_{0} {Z}_{k} .$$

Each of the stabilizer check qubit device, the two or more data qubit devices, and the respective tunable-frequency coupler device is a tunable-frequency transmon qubit device. The quantum error correction scheme is based on a surface error correction code. The method further includes prior to applying the multi-qubit quantum logic gate, obtaining device parameters for the stabilizer check qubit device, the two or more data qubit devices, and the respective tunable-frequency coupler devices of the superconducting quantum processing unit; and determining control parameters for applying the multi-qubit quantum logic gate to the stabilizer check qubit device and the two or more data qubit devices according to the qubit device parameters.

Implementations of the second example may include one or more of the following features. Determining the control parameters includes determining parking values of respective coupler flux biases for flux bias signals to deactivate the respective tunable-frequency coupler devices. The method further includes after applying the multi-qubit quantum logic gate, performing a qubit readout measurement on the stabilizer check qubit device. The method includes prior to performing the qubit readout measurement, applying the coupler flux biases at the parking values to the respective tunable-frequency coupler devices in parallel to deactivate the respective tunable-frequency coupler devices in parallel during a time step such that the stabilizer check qubit device is decoupled to the two or more data qubit devices during the time step.

Implementations of the second example may include one or more of the following features. Determining the control parameters includes determining gate-activating values of respective coupler flux biases for flux bias signals to activate the respective tunable-frequency coupler devices. Applying the multi-qubit quantum logic gate includes applying the coupler flux biases at the gate-activating values to the respective tunable-frequency coupler devices in parallel to activate the respective tunable-frequency coupler devices in parallel during a time step such that the stabilizer check qubit device is coupled to the two or more data qubit devices during the time step. The method includes executing a quantum program. The quantum program includes the multi-qubit quantum logic gate and at least one single-qubit quantum logic gate.

In a third example, a quantum computing system includes a superconducting quantum processing unit including a stabilizer check qubit device and two or more data qubit devices coupled to the stabilizer check qubit device through respective tunable-frequency coupler devices; and means for applying a multi-qubit quantum logic gate on the stabilizer check qubit device and the two or more data qubit devices of the superconducting quantum processing unit. Applying the multi-qubit quantum logic gate includes evolving the stabilizer check qubit device and the two or more data qubit devices under an interaction Hamiltonian. The interaction Hamiltonian includes a plurality of terms; and each of the plurality of terms corresponding to an interaction between the stabilizer check qubit device and a respective one of the two or more data qubit devices. Each of the terms includes a phase combined with a Pauli operator applied to the stabilizer check qubit device and the Pauli operator applied to the respective one of the two or more data qubit devices.

In a fourth example, a superconducting quantum processing unit includes a stabilizer check qubit device and two or more data qubit devices operably coupled to the stabilizer check qubit device through respective tunable-frequency coupler devices. A method to perform a multi-qubit stabilizer measurement in the superconducting quantum processing unit includes activating, through the respective tunable-frequency coupler devices, dispersive interactions between each of the two or more data qubit devices and the stabilizer check qubit device such that the stabilizer check qubit device is coupled to the two or more data qubit devices in parallel during a time step. Each dispersive interaction has a determined dispersive interaction strength value. The method further includes while the dispersive interactions are activated, encoding information from the two or more data qubit devices onto the stabilizer check qubit device in parallel during the time step; deactivating the dispersive interactions such that the stabilizer check qubit device is decoupled from the two or more data qubit devices; and performing a qubit readout measurement on the stabilizer check qubit device. The encoded information is usable by a quantum error correction scheme.

Implementations of the fourth example may include one or more of the following features. Activating the dispersive interactions includes applying coupler flux biases at gate-activating values to the respective tunable-frequency coupler devices in parallel to activate the respective tunable-frequency coupler devices in parallel during the time step. Deactivating the dispersive interactions includes applying coupler flux biases at parking values to the respective tunable-frequency coupler devices in parallel to deactivate the respective tunable-frequency coupler devices in parallel. Each of the stabilizer check qubit device, the two or more data qubit devices, and the respective tunable-frequency coupler device is a tunable-frequency transmon qubit device. The quantum error correction scheme is based on a surface error correction code.

Implementations of the fourth example may include one or more of the following features. Encoding the information from the two or more data qubit devices to the stabilizer check qubit device includes applying a multi-qubit quantum logic gate on the stabilizer check qubit device and the two or more data qubit devices of the superconducting quantum processing unit. Applying the multi-qubit quantum logic gate includes evolving the stabilizer check qubit device and the two or more data qubit devices under an interaction Hamiltonian, the interaction Hamiltonian comprising a plurality of terms. Each of the plurality of terms corresponds to an interaction between the stabilizer check qubit device and a respective one of the two or more data qubit devices. Each of the terms includes a phase combined with a Pauli operator applied to the stabilizer check qubit device and the Pauli operator applied to the respective one of the two or more data qubit devices. The interaction Hamiltonian has a form indicative of at least:

$$H = χ {\sum }_{k = 1}^{n} {σ}_{0}^{i} {σ}_{k}^{i} ,$$

where n represents the number of the two or more data qubit devices, χ represents the phase,

$${σ}_{0}^{i}$$

represents the Pauli operator applied to the stabilizer check qubit device,

$${σ}_{k}^{i}$$

represents the Pauli operator applied to the k^{th} data qubit device, and k is an integer. When the Pauli operator is the Pauli-Z operator, the interaction Hamiltonian has a form indicative of at least:

$$H = χ {\sum }_{k = 1}^{n} {Z}_{0} {Z}_{k} .$$

The determined dispersive interaction strength value is greater than a respective decay rate of a respective qubit device.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple implementations separately or in any suitable sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of embodiments have been described. Nevertheless, it will be understood that various modifications can be made. Accordingly, other embodiments are within the scope of the following claims.

1. A method for operating a superconducting quantum processing unit comprising a stabilizer check qubit device and two or more data qubit devices operably coupled to the stabilizer check qubit device through respective tunable-frequency coupler devices, the method comprising:
applying a multi-qubit quantum logic gate on the stabilizer check qubit device and the two or more data qubit devices of the superconducting quantum processing unit, the multi-qubit quantum logic gate encoding information from the two or more data qubit devices onto the stabilizer check qubit device, the encoded information usable by a quantum error correction scheme,
wherein applying the multi-qubit quantum logic gate comprises evolving the stabilizer check qubit device and the two or more data qubit devices under an interaction Hamiltonian, the interaction Hamiltonian comprising a plurality of terms, each of the plurality of terms corresponding to an interaction between the stabilizer check qubit device and a respective one of the two or more data qubit devices, each of the terms comprising a phase combined with a Pauli operator applied to the stabilizer check qubit device and the Pauli operator applied to the respective one of the two or more data qubit devices.

2. The method of claim 1, wherein the interaction Hamiltonian has a form indicative of at least:
$$H = χ {\sum }_{k = 1}^{n} {σ}_{0}^{i} {σ}_{k}^{i}$$
where n represents the number of the two or more data qubit devices, x represents the phase,
$${σ}_{0}^{i}$$
represents the Pauli operator applied to the stabilizer check quoi device,
$${σ}_{k}^{i}$$
represents the Pauli operator applied to the k^{th} data qubit device, and k is an integer.

3. The method of claim 2, wherein the Pauli operator is the Pauli-Z operator, and the interaction Hamiltonian has a form indicative of at least:
$$H = χ {\sum }_{k = 1}^{n} {Z}_{0} {Z}_{k} .$$

4. The method of claim 1, wherein each of the stabilizer check qubit device, the two or more data qubit devices, and the respective tunable-frequency coupler device is a tunable-frequency transmon qubit device.

5. The method of claim 1, wherein the quantum error correction scheme is based on a surface error correction code.

6. The method of claim 1, comprising:
prior to applying the multi-qubit quantum logic gate, obtaining device parameters for the stabilizer check qubit device, the two or more data qubit devices, and the respective tunable-frequency coupler devices of the superconducting quantum processing unit; and
determining control parameters for applying the multi-qubit quantum logic gate to the stabilizer check qubit device and the two or more data qubit devices according to the qubit device parameters.

7. The method of claim 6, wherein determining the control parameters comprises:
determining parking values of respective coupler flux biases for flux bias signals to deactivate the respective tunable-frequency coupler devices.

8. The method of claim 7, comprising:
after applying the multi-qubit quantum logic gate, performing a qubit readout measurement on the stabilizer check qubit device.

9. The method of claim 8, comprising:
prior to performing the qubit readout measurement, applying the coupler flux biases at the parking values to the respective tunable-frequency coupler devices in parallel to deactivate the respective tunable-frequency coupler devices in parallel during a time step such that the stabilizer check qubit device is decoupled to the two or more data qubit devices during the time step.

10-12. (canceled)

13. A quantum computing system comprising:
a superconducting quantum processing unit comprising a stabilizer check qubit device and two or more data qubit devices coupled to the stabilizer check qubit device through respective tunable-frequency coupler devices; and
a control system communicably coupled to the superconducting quantum processing unit and operable to perform operations comprising:
applying a multi-qubit quantum logic gate on the stabilizer check qubit device and the two or more data qubit devices of the superconducting quantum processing unit, the multi-qubit quantum logic gate encoding information from the two or more data qubit devices onto the stabilizer check qubit device, the encoded information usable by a quantum error correction scheme,
wherein applying the multi-qubit quantum logic gate comprises evolving the stabilizer check qubit device and the two or more data qubit devices under an interaction Hamiltonian, the interaction Hamiltonian comprising a plurality of terms, each of the plurality of terms corresponding to an interaction between the stabilizer check qubit device and a respective one of the two or more data qubit devices, each of the terms comprising a phase combined with a Pauli operator applied to the stabilizer check qubit device and the Pauli operator applied to the respective one of the two or more data qubit devices.

14. The system of claim 13, wherein the interaction Hamiltonian a form indicative of at least:
$$H = χ {\sum }_{k = 1}^{n} {σ}_{0}^{i} {σ}_{k}^{i}$$
where n represents the number of the two or more data qubit devices, χ represents the phase
$${σ}_{0}^{i}$$
represents the Pauli operator applied to the stabilizer check qubit device, and
$${σ}_{k}^{i}$$
represents the Pauli operator applied to the k^{th} data qubit device, and k is an integer.

15. The system of claim 14, wherein the Pauli operator is the Pauli-Z operator, and the interaction Hamiltonian has a form indicative of at least:
$$H = χ {\sum }_{k = 1}^{n} {Z}_{0} {Z}_{k} .$$

16. The system of claim 13, wherein each of the stabilizer check qubit device, the two or more data qubit devices, and the respective tunable-frequency coupler device is a tunable-frequency transmon qubit device.

17. The system of claim 13, wherein the quantum error correction scheme is based on a surface error correction code.

18. The system of claim 13, wherein the operations comprise:
prior to applying the multi-qubit quantum logic gate, obtaining device parameters for the stabilizer check qubit device, the two or more data qubit devices, and the respective tunable-frequency coupler devices of the superconducting quantum processing unit; and
determining control parameters for applying the multi-qubit quantum logic gate to the stabilizer check qubit device and the two or more data qubit devices according to the qubit device parameters.

19. The system of claim 18, wherein determining the control parameters comprises:
determining parking values of respective coupler flux biases for flux bias signals to deactivate the respective tunable-frequency coupler devices.

20. The system of claim 19, wherein the operations comprise:
after applying the multi-qubit quantum logic gate, performing a qubit readout measurement on the stabilizer check qubit device.

21. The system of claim 20, wherein the operations comprise:
prior to performing the qubit readout measurement, applying the coupler flux biases at the parking values to the respective tunable-frequency coupler devices in parallel to deactivate the respective tunable-frequency coupler devices in parallel during a time step such that the stabilizer check qubit device is decoupled to the two or more data qubit devices during the time step.

22. The system of claim 18, wherein determining the control parameters comprises:
determining gate-activating values of respective coupler flux biases for flux bias signals to activate the respective tunable-frequency coupler devices.

23. (canceled)

24. A quantum computing system comprising:
a superconducting quantum processing unit comprising a stabilizer check qubit device and two or more data qubit devices coupled to the stabilizer check qubit device through respective tunable-frequency coupler devices; and
means for applying a multi-qubit quantum logic gate on the stabilizer check qubit device and the two or more data qubit devices of the superconducting quantum processing unit, the multi-qubit quantum logic gate encoding information from the two or more data qubit devices onto the stabilizer check qubit device the encoded information usable by a quantum error correction scheme,
wherein applying the multi-qubit quantum logic gate comprises evolving the stabilizer check qubit device and the two or more data qubit devices under an interaction Hamiltonian, the interaction Hamiltonian comprising a plurality of terms, each of the plurality of terms corresponding to an interaction between the stabilizer check qubit device and a respective one of the two or more data qubit devices, each of the terms comprising a phase combined with a Pauli operator applied to the stabilizer check qubit device and the Pauli operator applied to the respective one of the two or more data qubit devices.

25-33. (canceled)
